(19) United States
(12) Patent Application Publication
(10) Pub. No.: US 2024/0222353 A1
(43) Pub. Date: Jul. 4, 2024

(54) TRANSFORMER CHIP

(71) Applicant: ROHM CO., LTD., Kyoto (JP)

(72) Inventors: Toru HIGUCHI, Kyoto-shi (JP); Eiji KUWAHARA, Kyoto-shi (JP)

(73) Assignee: ROHM CO., LTD., Kyoto (JP)

(21) Appl. No.: 18/606,316

(22) Filed: Mar. 15, 2024

Related U.S. Application Data
(63) Continuation of application No. PCT/JP2022/034857, filed on Sep. 16, 2022.

(30) Foreign Application Priority Data
Sep. 21, 2021 (JP) 2021-153289

(51) Int. Cl. H01L 27/01; H01F 27/28; H01F 27/32

(52) U.S. Cl. CPC H01L 27/01; H01F 27/2804; H01F 27/323; H01F 2027/2809; H01F 27/327

(57) ABSTRACT

This transformer chip includes a first coil and a second coil provided on a substrate major surface of a substrate. The first coil and the second coil are arranged along a first direction on the substrate major surface of the substrate. The first coil includes first substrate wires and first connection wires arrayed in an X-direction. The first substrate wires extend along a direction transverse to the X-direction. The first connection wires are each connected between two first substrate wires adjacent to each other in the X-direction. The second coil includes second substrate wires and second connection wires arrayed in the X-direction. The second substrate wires extend along the direction transverse to the X-direction. The second connection wires are each connected between two second substrate wires adjacent to each other in the X-direction.

### BACKGROUND

The present disclosure relates to a transformer chip.

A conventional insulation element such as a transformer chip is used to transmit a signal between semiconductor chips that differ in power supply voltage. Japanese Laid-Open Patent Publication No. 2018-78169 discloses an example of a transformer chip including two coils vertically spaced apart and opposed to each other.

### BRIEF DESCRIPTION OF DRAWINGS

FIG. 1 is a perspective view showing a first embodiment of a transformer chip.

FIG. 2 is a plan view of the transformer chip shown in FIG. 1.

FIG. 3 is a cross-sectional view taken along line 3-3 in FIG. 2.

FIG. 4 is a cross-sectional view taken along line 4-4 in FIG. 2.

FIG. 5 is a plan view of a first coil.

FIG. 6 is a plan view of a second coil.

FIG. 7 is a circuit diagram showing an example of usage of a transformer chip.

FIG. 8 is a perspective view showing a second embodiment of a transformer chip.

FIG. 9 is a plan view of the transformer chip shown in FIG. 8.

FIG. 10 is a cross-sectional view taken along line 10-10 in FIG. 9.

FIG. 11 is a cross-sectional view taken along line 11-11 in FIG. 9.

FIG. 12 is a perspective view showing a third embodiment of a transformer chip.

FIG. 13 is a plan view of the transformer chip shown in FIG. 12.

FIG. 14 is a cross-sectional view taken along line 14-14 in FIG. 13.

FIG. 15 is a cross-sectional view taken along line 15-15 in FIG. 13.

FIG. 16 is a cross-sectional view showing a modified example of a transformer chip.

FIG. 17 is a cross-sectional view showing a modified example of a transformer chip.

FIG. 18 is a plan view showing a modified example of a transformer chip.

FIG. 19 is a plan view showing a modified example of a transformer chip.

FIG. 20 is a plan view showing a modified example of a transformer chip.

FIG. 21 is a plan view showing a modified example of a transformer chip.

FIG. 22 is a plan view showing a modified example of a transformer chip.

FIG. 23 is a plan view showing a modified example of a transformer chip.

FIG. 24 is a cross-sectional view showing a modified example of a transformer chip.

### DETAILED DESCRIPTION

Embodiments of a transformer chip according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

In the present disclosure, terms such as “first,” “second,” and “third” are used as labels and are not intended to sequence objects of the labels.

### First Embodiment

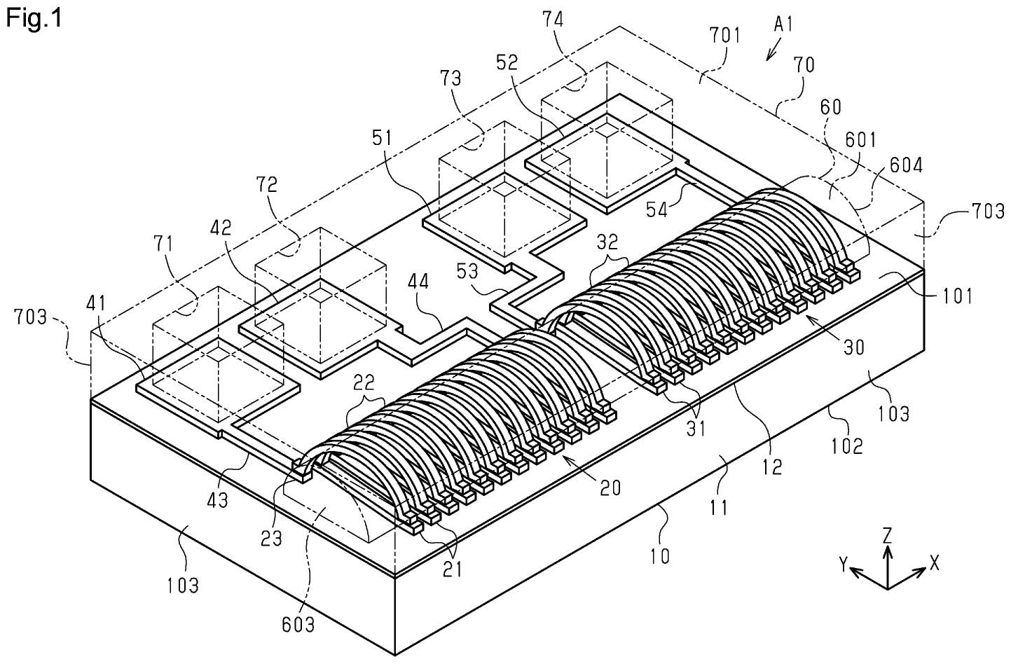

A first embodiment of a transformer chip A1 will now be described with reference to FIGS. 1 to 5.

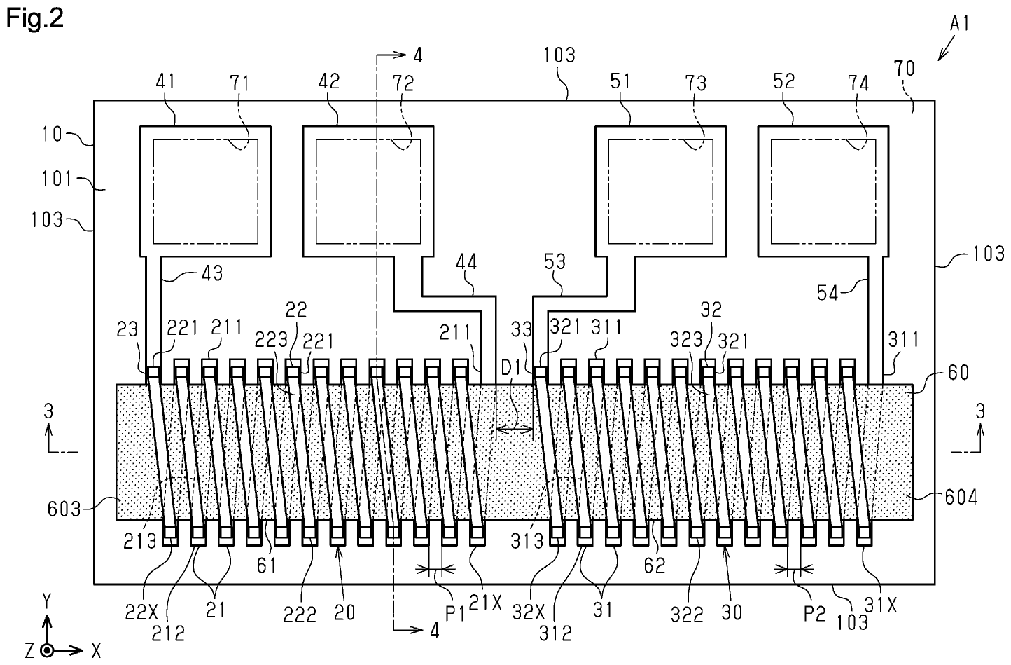

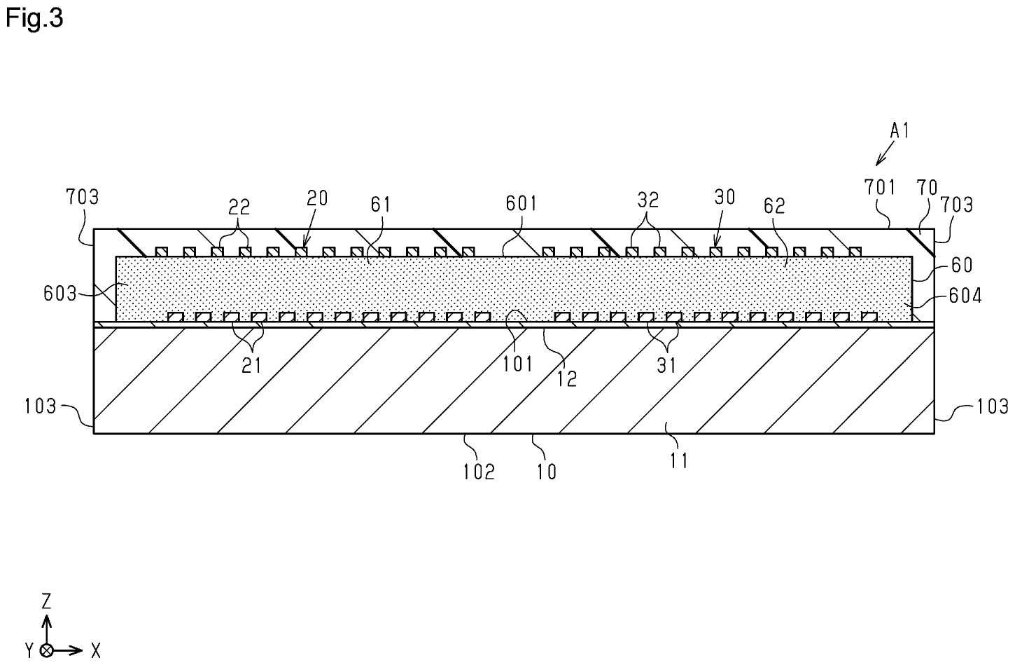

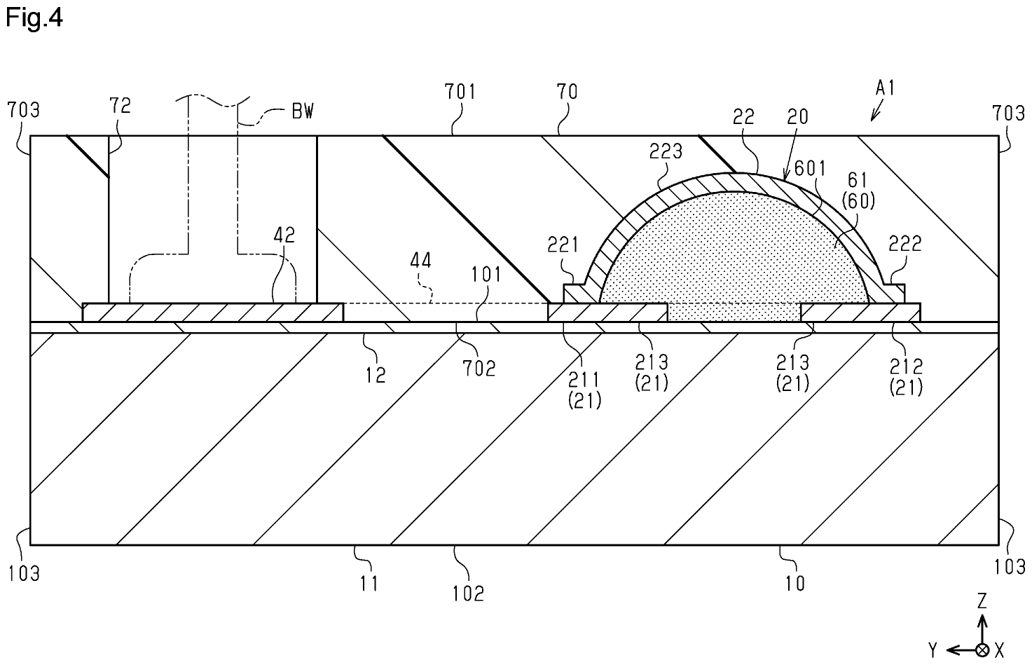

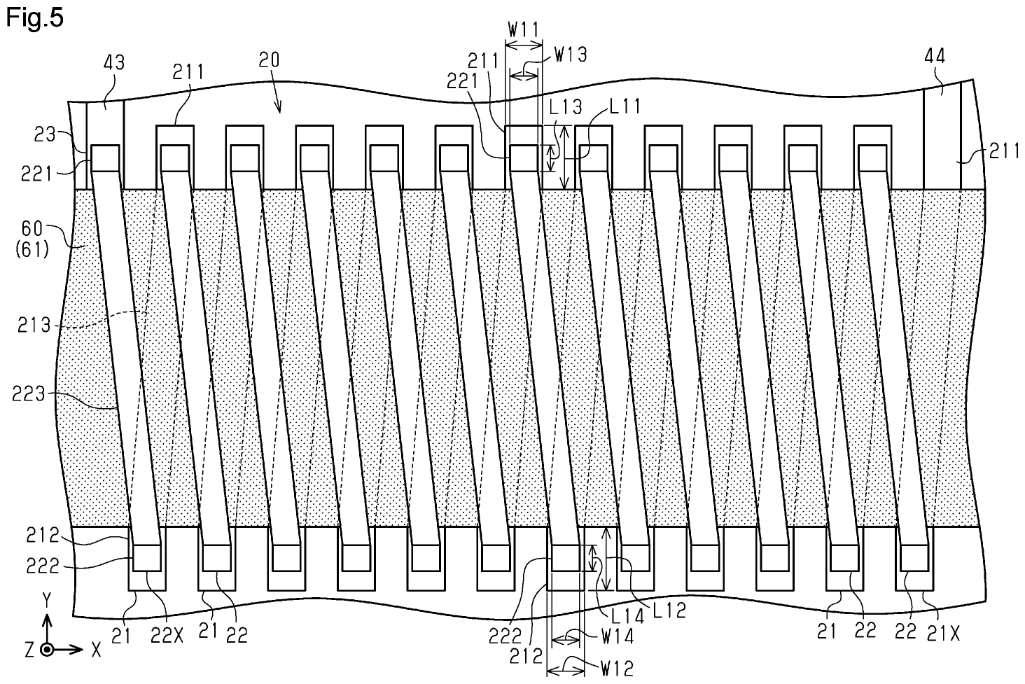

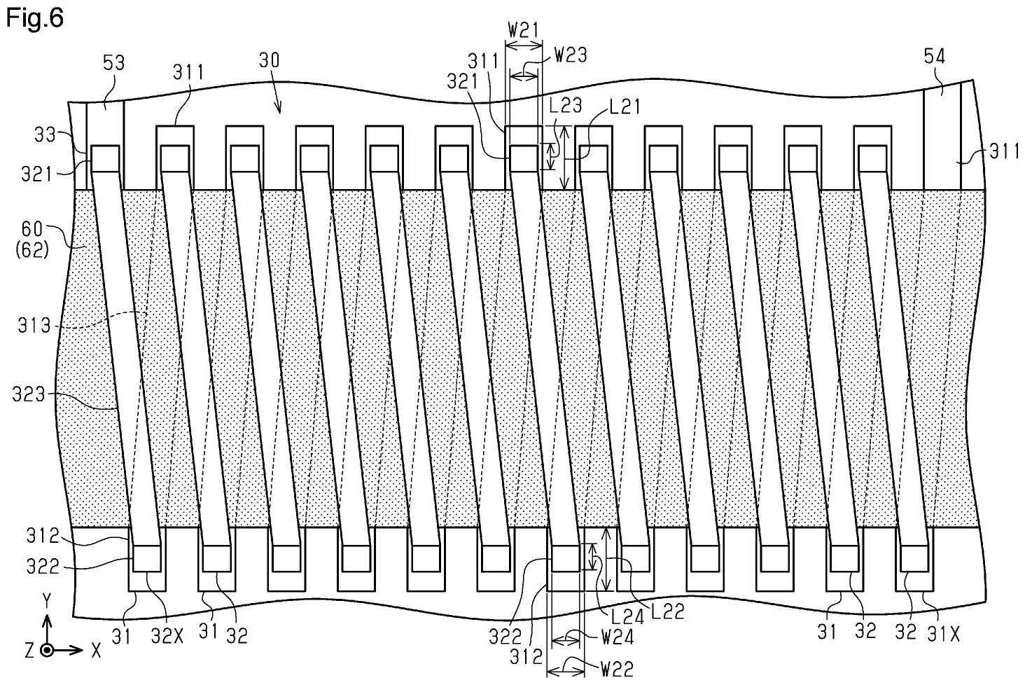

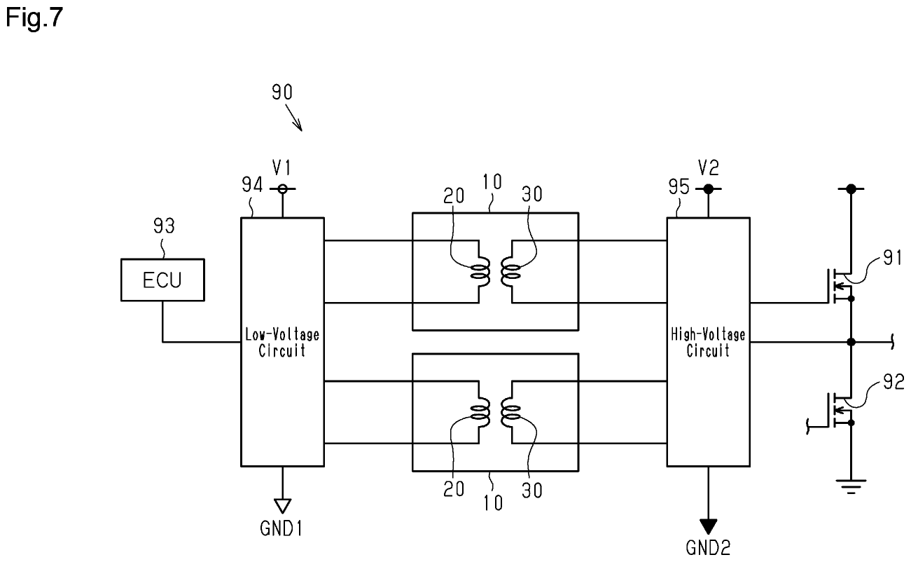

FIG. 1 is a perspective view of the transformer chip A1. FIG. 2 is a plan view of the transformer chip A1. FIG. 3 is a cross-sectional view taken along line 3-3 in FIG. 2. FIG. 4 is a cross-sectional view taken along line 4-4 in FIG. 2. FIG. 5 is an enlarged plan view of a first coil 20. FIG. 6 is an enlarged plan view of a second coil 30. FIG. 7 is a circuit diagram showing an example of usage of the transformer chip A1.

As shown in FIGS. 1 to 4, the transformer chip A1 includes a substrate 10, the first coil 20, the second coil 30, input pads 41 and 42, output pads 51 and 52, an insulation member 60, and an encapsulation resin 70.

### Substrate

The substrate 10 has the form of a substantially flat plate. In the description hereafter, the thickness-wise direction of the substrate 10 is referred to as a Z-direction. The Z-direction is orthogonal to a first direction and a second direction that are orthogonal to each other and referred to as an X-direction and a Y-direction.

As shown in FIG. 2, as viewed in the Z-direction, the substrate 10 is rectangular so that the long sides extend in the X-direction and the short sides extend in the Y-direction.

The substrate 10 includes a substrate main surface 101, a substrate back surface 102, and substrate side surfaces 103. The substrate main surface 101 and the substrate back surface 102 face opposite directions in the Z-direction. The substrate main surface 101 and the substrate back surface 102 are flat. The substrate side surfaces 103 face in one of the X-direction and the Y-direction. The substrate side surfaces 103 are located between the substrate main surface 101 and the substrate back surface 102.

In the present embodiment, the substrate 10 includes a substrate body 11 and an insulation film 12. The substrate body 11 is composed of, for example, a semiconductor substrate. The insulation film 12 is an electrically insulating film. The substrate 10 maybe formed from an insulative resin.

In the present embodiment, the substrate body 11 is a substrate formed from a material including silicon (Si). As the semiconductor substrate, a wide-bandgap semiconductor or a compound semiconductor may be used for the substrate 10. The wide-bandgap semiconductor may be silicon carbide (SiC). The compound semiconductor may be a group III-V compound semiconductor. The compound semiconductor may include at least one of aluminum nitride (AlN), indium nitride (InN), gallium nitride (GaN), and gallium arsenide (GaAs). Alternatively, instead of the semiconductor substrate, an insulating substrate formed from a glass-containing material may be used as the substrate body 11. Alternatively, a substrate formed from a synthetic resin that includes, for example, an epoxy resin as a main component may be used as the substrate body 11.

In an example, the insulation film 12 is formed from silicon oxide (SiO₂). In an example, the insulation film 12 is formed by, for example, thermally oxidizing the substrate body 11, which is a Si substrate. The material of the insulation film 12 and the process for forming the insulation film 12 are not limited. In an example, the insulation film 12 maybe formed from an element including SiO₂ and resin. Alternatively, the insulation film 12 may be formed from silicon nitride (SiN), aluminum nitride (AiN), or the like. The insulation film 12 maybe formed from resin.

As described above, the substrate 10 includes the substrate body 11 and the insulation film 12. The substrate 10 includes the substrate main surface 101, the substrate back surface 102, and the substrate side surfaces 103. The substrate main surface 101 is defined by a front surface of the insulation film 12. The substrate back surface 102 is defined by a back surface of the substrate body 11. The substrate side surfaces 103 are each defined by a side surface of the substrate body 11 and a side surface of the insulation film 12.

### First Coil, Second Coil, and Insulation Member

The first coil 20 and the second coil 30 are arranged on the substrate main surface 101 of the substrate 10. The first coil 20 and the second coil 30 are arranged on the substrate main surface 101 along the substrate main surface 101. In the present embodiment, the first coil 20 and the second coil 30 are arranged next to each other in the X-direction on the substrate main surface 101.

The first coil 20 includes first substrate wires 21 and first connection wires 22. The first substrate wires 21 and the first connection wires 22 are formed from, for example, a conductive metal such as copper (Cu) or a Cu alloy.

As shown in FIGS. 1 and 2, the first substrate wires 21 are arranged on the substrate main surface 101 of the substrate 10. As shown in FIG. 2, the first substrate wires 21 are arranged next to each other in the X-direction, in which the first coil 20 and the second coil 30 are arranged next to each other. The first substrate wires 21 extend in a direction intersecting the X-direction.

As shown in FIGS. 2 and 5, in the present embodiment, each of the first substrate wires 21 includes a first end 211, a second end 212 opposite to the first end 211, and a first conductor 213 located between the first end 211 and the second end 212.

As viewed in the Z-direction, the first end 211 and the second end 212 are rectangular and are elongated in the Y-direction as compared to the X-direction.

In the present embodiment, as viewed in the Z-direction, the first end 211 of each first substrate wire 21 is shifted from the second end 212 in the X-direction (rightward in FIG. 5). As viewed in the Z-direction, in the X-direction, the first end 211 of each first substrate wire 21 is located between the second end 212 of the first substrate wire 21 and the second end 212 of one of the first substrate wires 21 located adjacent to the first substrate wire 21 in the X-direction.

The first conductor 213 connects the first end 211 and the second end 212. Hence, as viewed in the Z-direction, the first conductor 213 of each first substrate wire 21 extends at a predetermined angle from the Y-direction. As shown in FIG. 2, as viewed in the Z-direction, the first conductor 213 is inclined from the second end 212 toward the first end 211 so as to approach the second coil 30. In other words, as viewed in the Z-direction, the first conductor 213 is inclined from the first end 211 toward the second end 212 so as to separate away from the second coil 30.

In the present embodiment, an end of the first coil 20 located at a side opposite from the second coil 30 includes a first connector 23. In the same manner as the first ends 211 of the first substrate wires 21, the first connector 23 is rectangular and is elongated in the Y-direction as compared to the X-direction. As viewed in the Z-direction, the first connector 23 and the first ends 211 of the first substrate wires 21 are located at the same position in the Y-direction. As viewed in the Z-direction, the first connector 23 is arranged so that the distance between the first connector 23 and an adjacent one of the first ends 211 in the X-direction is equal to the distance between two of the first ends 211 in the X-direction.

As shown in FIGS. 2 and 3, the insulation member 60 is formed to extend through the first coil 20 and the second coil 30. More specifically, the insulation member 60 includes a first end 603 projecting from the first coil 20 in a direction away from the second coil 30 and a second end 604 projecting from the second coil 30 in a direction away from the first coil 20. The insulation member 60 is formed from, for example, a phenol resin or a polyimide resin.

The insulation member 60 includes a first part 61 corresponding to the first coil 20 and a second part 62 corresponding to the second coil 30. As shown in FIG. 3, the first part 61 is located between the first substrate wires 21 and the first connection wires 22 of the first coil 20. The second part 62 is located between second substrate wires 31 and second connection wires 32 of the second coil 30.

As shown in FIGS. 2 and 5, the insulation member 60 is formed to cover the first substrate wires 21. More specifically, as shown in FIGS. 2, 4, and 5, the insulation member 60 is formed to expose the first ends 211 and the second ends 212 and cover the first conductors 213. As shown in FIGS. 3 and 4, the insulation member 60 is in contact with the substrate main surface 101 and covers the first conductors 213 of the first substrate wires 21. As shown in FIG. 3, the insulation member 60 is in contact with an upper surface and side surfaces of the first conductors 213.

As shown in FIG. 4, in the Z-direction, the insulation member 60 is in contact with the substrate main surface 101 and is bulged in a direction away from the substrate main surface 101. In a plane (YZ-plane) orthogonal to the X-direction, the insulation member 60 has an arcuate cross section that is bulged in a direction away from the substrate main surface 101. The insulation member 60 is strip-shaped and extends in the X-direction.

As shown in FIGS. 2, 3, and 5, the first connection wires 22 are arranged next to each other in the X-direction, in which the first coil 20 and the second coil 30 are arranged next to each other. The first connection wires 22 extend in a direction intersecting the X-direction.

As shown in FIG. 4, the first connection wire 22 is in contact with the insulation member 60 and, in a plane orthogonal to the X-direction, has a cross section extending along the arcuate surface of the insulation member 60. The insulation member 60 separates a central part of the first connection wire 22 away from the first substrate wire 21 in the Z-direction. Each of the first connection wires 22 is located adjacent to two of the first substrate wires 21 in the X-direction and connects the first end 211 of one of the two of the first substrate wires 21 and the second end 212 of the other one of the two of the first substrate wires 21.

As shown in FIGS. 2 and 5, in the present embodiment, each of the first connection wires 22 includes a third end 221, a fourth end 222 opposite to the third end 221, and a second conductor 223 located between the third end 221 and the fourth end 222.

As viewed in the Z-direction, the third end 221 and the fourth end 222 are rectangular and are elongated in the Y-direction as compared to the X-direction.

In the present embodiment, as viewed in the Z-direction, the third end 221 of each first connection wire 22 is shifted from the fourth end 222 in the X-direction (rightward in FIG. 5). As viewed in the Z-direction, in the X-direction, the third end 221 of each first connection wire 22 is located between the fourth end 222 of the first connection wire 22 and the fourth end 222 of one of the first connection wires 22 located adjacent to the first connection wire 22 in the X-direction.

The third end 221 of the first connection wire 22 is connected to the first end 211 of the first substrate wire 21. The fourth end 222 of the first connection wire 22 is connected to the second end 212 of one of the first substrate wires 21 located adjacent to the first substrate wire 21 that is connected to the third end 221. That is, each first connection wire 22 is connected between two of the first substrate wires 21 located adjacent to the each other in the X-direction.

The second conductor 223 connects the third end 221 and the fourth end 222. Hence, as viewed in the Z-direction, the second conductor 223 of each first connection wire 22 extends at a predetermined angle from the Y-direction. As shown in FIG. 2, as viewed in the Z-direction, the second conductor 223 is inclined from the fourth end 222 toward the third end 221 so as to extend away from the second coil 30. In other words, as viewed in the Z-direction, the second conductor 223 is inclined from the third end 221 toward the fourth end 222 so as to approach the second coil 30.

In the present embodiment, one of the first substrate wires 21 located at the end close to the second coil 30 is referred to as a first substrate wire 21X. The first end 211 of the first substrate wire 21X is not connected to the first connection wires 22. In the present embodiment, one of the first connection wires 22 located at the end opposite from the second coil 30 is referred to as a first connection wire 22X. The third end 221 of the first connection wire 22X is connected to the first connector 23 of the first coil 20.

As shown in FIG. 5, the width of the first connection wires 22 is smaller than the width of the first substrate wires 21.

As described above, the first substrate wires 21 each include the first end 211, the second end 212, and the first conductor 213. As viewed in the Z-direction, the first end 211 and the second end 212 are rectangular and are elongated in the Y-direction as compared to the X-direction.

The first connection wires 22 each include the third end 221, the fourth end 222, and the second conductor 223. As viewed in the Z-direction, the third end 221 and the fourth end 222 are rectangular and are elongated in the Y-direction as compared to the X-direction.

A width W13 of the third end 221 is smaller than a width W11 of the first end 211. A length L13 of the third end 221 is smaller than a length L11 of the first end 211. In the same manner, a width W14 of the fourth end 222 is smaller than a width W12 of the second end 212. A length L14 of the fourth end 222 is smaller than a length L12 of the second end 212.

In the present embodiment, the width W11 of the first end 211 in the X-direction is equal to the width W12 of the second end 212 in the X-direction. The length L11 of the first end 211 in the Y-direction is equal to the length L12 of the second end 212 in the Y-direction. The width W13 of the third end 221 in the X-direction is equal to the width W14 of the fourth end 222 in the X-direction. The length L13 of the third end 221 in the Y-direction is equal to the length L14 of the fourth end 222 in the Y-direction. In this specification, the expressions “the widths are equal” and “the lengths are equal” include a difference that is within a manufacturing tolerance range.

In the present embodiment, in the X-direction, the width of the first conductor 213 is equal to the width of the first end 211 and the width of the second end 212. In the X-direction, the width of the second conductor 223 is equal to the width of the third end 221 and the width of the fourth end 222. Alternatively, the width of the first conductor 213 may differ from the width of the first end 211 and the width of the second end 212. Also, the width of the second conductor 223 may differ from the width of the third end 221 and the width of the fourth end 222.

As shown in FIGS. 2 and 3, the second coil 30 includes second substrate wires 31 and second connection wires 32. The second substrate wires 31 and the second connection wires 32 are formed from, for example, a conductive metal such as copper (Cu) or a Cu alloy.

As shown in FIGS. 1 and 2, the second substrate wires 31 are arranged on the substrate main surface 101 of the substrate 10. As shown in FIG. 2, the second substrate wires 31 are arranged next to each other in the X-direction, in which the first coil 20 and the second coil 30 are arranged next to each other. The second substrate wires 31 extend in a direction intersecting the X-direction.

As shown in FIGS. 2 and 6, in the present embodiment, each of the second substrate wires 31 includes a first end 311, a second end 312 opposite to the first end 311, and a first conductor 313 located between the first end 311 and the second end 312.

As viewed in the Z-direction, the first end 311 and the second end 312 are rectangular and are elongated in the Y-direction as compared to the X-direction.

In the present embodiment, as viewed in the Z-direction, the first end 311 of each second substrate wire 31 is shifted from the second end 312 in the X-direction (rightward in FIG. 6). As viewed in the Z-direction, in the X-direction, the first end 311 of each second substrate wire 31 is located between the second end 312 of the second substrate wire 31 and the second end 312 of one of the second substrate wires 31 located adjacent to the second substrate wire 31 in the X-direction.

The first conductor 313 connects the first end 311 and the second end 312. Hence, as viewed in the Z-direction, the first conductor 313 of each second substrate wire 31 extends at a predetermined angle from the Y-direction. As shown in FIG. 2, as viewed in the Z-direction, the first conductor 313 is inclined from the second end 312 toward the first end 311 so as to extend away from the first coil 20. In other words, as viewed in the Z-direction, the first conductor 313 is inclined from the first end 311 toward the second end 312 so as to approach the first coil 20.

In the present embodiment, an end of the second coil 30 located at the side of the first coil 20 includes a second connector 33. In the same manner as the first ends 311 of the second substrate wires 31, the second connector 33 is rectangular and is elongated in the Y-direction as compared to the X-direction. As viewed in the Z-direction, the second connector 33 and the first ends 311 of the second substrate wires 31 are located at the same position in the Y-direction. As viewed in the Z-direction, the second connector 33 is arranged so that the distance between the second connector 33 and an adjacent one of the first ends 311 in the X-direction is equal to the distance between two of the first ends 311 in the X-direction.

As shown in FIGS. 2, 3, and 6, the insulation member 60 is formed to cover the second substrate wires 31. More specifically, as shown in FIGS. 2 and 6, the insulation member 60 is formed to expose the first ends 311 and the second ends 312 and cover the first conductors 313. As shown in FIG. 3, the insulation member 60 is in contact with the substrate main surface 101 and covers the first conductors 313 of the second substrate wires 31. As shown in FIG. 3, the insulation member 60 is in contact with an upper surface and side surfaces of the first conductors 313.

As shown in FIGS. 2, 3, and 6, the second connection wires 32 are arranged next to each other in the X-direction, in which the first coil 20 and the second coil 30 are arranged next to each other. The second connection wires 32 extend in a direction intersecting the X-direction.

In the same manner as the first connection wire 22 of the first coil 20 shown in FIG. 4, the second connection wire 32 is in contact with the insulation member 60 and, in a plane orthogonal to the X-direction, has a cross section extending along the arcuate surface of the insulation member 60. The insulation member 60 separates a central part of the second connection wire 32 away from the second substrate wire 31 in the Z-direction. Each of the second connection wires 32 is located adjacent to two of the second substrate wires 31 in the X-direction and connects the first end 311 of one of the two of the second substrate wires 31 and the second end 312 of the other one of the two of the second substrate wires 31.

As shown in FIGS. 2 and 6, in the present embodiment, each of the second connection wires 32 includes a third end 321, a fourth end 322 opposite to the third end 321, and a second conductor 323 located between the third end 321 and the fourth end 322.

As viewed in the Z-direction, the third end 321 and the fourth end 322 are rectangular and are elongated in the Y-direction as compared to the X-direction.

In the present embodiment, as viewed in the Z-direction, the third end 321 of each second connection wire 32 is shifted from the fourth end 322 in the X-direction (rightward in FIG. 6). As viewed in the Z-direction, in the X-direction, the third end 321 of each second connection wire 32 is located between the fourth end 322 of the second connection wire 32 and the fourth end 322 of one of the second connection wires 32 located adjacent to the second connection wire 32 in the X-direction.

The third end 321 of the second connection wire 32 is connected to the first end 311 of the second substrate wire 31. The fourth end 322 of the second connection wire 32 is connected to the second end 312 of one of the second substrate wires 31 located adjacent to the second substrate wire 31 that is connected to the third end 321. That is, each second connection wire 32 is connected between two of the second substrate wires 31 located adjacent to the each other in the X-direction.

The second conductor 323 connects the third end 321 and the fourth end 322. Hence, as viewed in the Z-direction, the second conductor 323 of each second substrate wire 31 extends at a predetermined angle from the Y-direction. As shown in FIG. 2, as viewed in the Z-direction, the second conductor 323 is inclined from the fourth end 322 toward the third end 321 so as to approach the first coil 20. In other words, as viewed in the Z-direction, the second conductor 323 is inclined from the third end 321 toward the fourth end 322 so as to separate away from the first coil 20.

In the present embodiment, one of the second substrate wires 31 located at an end opposite from the first coil 20 is referred to as a second substrate wire 31X. The first end 311 of the second substrate wire 31X is not connected to the second connection wires 32. In the present embodiment, one of the second connection wires 32 located at the end close to the first coil 20 is referred to as a second connection wire 32X. The third end 321 of the second connection wire 32X is connected to the second connector 33 of the second coil 30.

As shown in FIG. 6, the width of the second connection wires 32 is smaller than the width of the second substrate wires 31.

As described above, the second substrate wires 31 each include the first end 311, the second end 312, and the first conductor 313. As viewed in the Z-direction, the first end 311 and the second end 312 are rectangular and are elongated in the Y-direction as compared to the X-direction.

The second connection wires 32 each include the third end 321, the fourth end 322, and the second conductor 323. As viewed in the Z-direction, the third end 321 and the fourth end 322 are rectangular and are elongated in the Y-direction as compared to the X-direction.

A width W23 of the third end 321 is smaller than a width W21 of the first end 311. A length L23 of the third end 321 is smaller than a length L21 of the first end 311. In the same manner as, a width W24 of the fourth end 322 is smaller than a width W22 of the second end 312. A length L24 of the fourth end 322 is smaller than a length L22 of the second end 312.

In the present embodiment, the width W21 of the first end 311 in the X-direction is equal to the width W22 of the second end 312 in the X-direction. The length L21 of the first end 311 in the Y-direction is equal to the length L22 of the second end 312 in the Y-direction. The width W23 of the third end 321 in the X-direction is equal to the width W24 of the fourth end 322 in the X-direction. The length L23 of the third end 321 in the Y-direction is equal to the length L24 of the fourth end 322 in the Y-direction.

In the present embodiment, in the X-direction, the width of the first conductor 313 is equal to the width of the first end 311 and the width of the second end 312. In the X-direction, the width of the second conductor 323 is equal to the width of the third end 321 and the width of the fourth end 322. Alternatively, the width of the first conductor 313 may differ from the width of the first end 311 and the width of the second end 312. The width of the second conductor 323 may differ from the width of the third end 321 and the width of the fourth end 322.

As shown in FIG. 2, the first coil 20 and the second coil 30 are separated from each other by a predetermined distance D1. The distance D1 is an inter-coil distance. The inter-coil distance may be specified by, for example, the distance between the first substrate wire 21 and the second substrate wire 31 or the distance between the first connection wire 22 and the second connection wire 32. The inter-coil distance D1 is set to be greater than a wire gap P1 of the first coil 20. The wire gap P1 is specified as the gap between two of the first substrate wires 21 located adjacent to each other in the X-direction. The inter-coil distance D1 is also set to be greater than a wire gap P2 of the second coil 30. The wire gap P2 is specified as the gap between two of the second substrate wires 31 located adjacent to each other in the X-direction. In the present embodiment, the wire gap P1 of the first coil 20 is equal to the wire gap P2 of the second coil 30. Alternatively, the wire gap P1 of the first coil 20 may differ from the wire gap P2 of the second coil 30.

### Input Pad and Output Pad

As shown in FIGS. 1 and 2, the transformer chip A1 includes the input pads 41 and 42 and the output pads 51 and 52. The input pads 41 and 42 and the output pads 51 and 52 are rectangular as viewed in the Z-direction. The input pads 41 and 42 and the output pads 51 and 52 are configured to be connectable to a bonding wire. In FIG. 4, a bonding wire BW connected to the input pad 42 is indicated by double-dashed lines. The input pad 41 and the output pads 51 and 52, shown in FIGS. 1 and 2, are also connected to a bonding wire in the same manner as the input pad 42.

The input pads 41 and 42 are connected to the first coil 20. More specifically, the input pad 41 is connected to the first connector 23 of the first coil 20 by a pad connection wire 43. The input pad 42 is connected to the first end 211 of the first substrate wire 21X of the first coil 20 by the pad connection wire 44. The input pads 41 and 42 and the pad connection wires 43 and 44 are formed from, for example, a conductive metal such as Cu or a Cu alloy.

The output pads 51 and 52 are connected to the second coil 30. More specifically, the output pad 51 is connected to the second connector 33 of the second coil 30 by a pad connection wire 53. The output pad 52 is connected to the first end 311 of the second substrate wire 31X of the second coil 30 by the pad connection wire 54. The output pads 51 and 52 and the pad connection wires 53 and 54 are formed from, for example, a conductive material such as Cu or a Cu alloy.

### Encapsulation Resin

As shown in FIGS. 1 to 4, the transformer chip A1 includes the encapsulation resin 70. As viewed in the Z-direction, the encapsulation resin 70 has the same size as the substrate 10. The encapsulation resin 70 includes a resin main surface 701, a resin back surface 702, and resin side surfaces 703. The resin main surface 701 and the resin back surface 702 face opposite directions in the Z-direction. The resin main surface 701 and the substrate main surface 101 of the substrate 10 face in the same direction. The resin side surfaces 703 face in one of the X-direction and the Y-direction.

The encapsulation resin 70 encapsulates the first coil 20 and the second coil 30. The encapsulation resin 70 includes openings 71 and 72 partially exposing the input pads 41 and 42. In addition, the encapsulation resin 70 includes openings 73 and 74 partially exposing the output pads 51 and 52. The encapsulation resin 70 is formed from, for example, a phenol resin or a polyimide resin. As shown in FIG. 4, the bonding wire BW is connected to a portion of the input pad 42 exposed from the opening 72 in the encapsulation resin 70. Although not shown, bonding wires are connected to portions of the input pad 41 and the output pads 51 and 52, shown in FIGS. 1 and 2, exposed from the openings 71, 73, and 74 in the encapsulation resin 70.

### Usage Examples

The transformer chip A1 of the present embodiment is used to insulate between an input and an output of various circuits.

FIG. 7 shows an example of a circuit in which the transformer chip A1 of the present embodiment is used.

The circuit is configured to apply a drive voltage signal to the gate of a switching element 91.

The switching element 91 is connected in series to a switching element 92. This forms an inverter device 90. The inverter device 90 is mounted on, for example, an electric car or a hybrid car. The switching element 91 is, for example, is a high-side switching element connected to a drive power supply. The switching element 92 is a low-side switching element. Examples of the switching elements 91 and 92 include transistors such as a Si metal-oxide-semiconductor field-effect transistor (Si MOSFET), a SiC MOSFET, and an insulated gate bipolar transistor (IGBT). In the description hereafter, SiC MOSFETs are used in the switching elements 91 and 92.

The transformer chip A1 is connected between a low-voltage circuit 94 and a high-voltage circuit 95.

The low-voltage circuit 94 is connected to an electronic control unit 93 (ECU) that controls the switching elements 91 and 92. The low-voltage circuit 94 is connected to the high-voltage circuit 95 by the transformer chip A1. The low-voltage circuit 94 is configured to be activated by a first voltage V1. The high-voltage circuit 95 is configured to be activated by a second voltage V2 that is higher than the first voltage V1. The first voltage V1 and the second voltage V2 are direct current voltage. In the present embodiment, ground GND1 of the low-voltage circuit 94 and ground GND2 of the high-voltage circuit 95 are arranged independently. The potential of the ground GND1 of the low-voltage circuit 94 is referred to as a first reference potential. The potential of the ground GND2 of the high-voltage circuit 95 is referred to as a second reference potential. In this case, the first voltage V1 is a voltage from the first reference potential, and the second voltage V2 is a voltage from the second reference potential.

The circuit is configured, based on a control signal from the ECU 93, to transmit a signal from the low-voltage circuit 94 to the high-voltage circuit 95 through the transformer chip A1 and output a drive voltage signal from the high-voltage circuit 95.

The signal transmitted from the low-voltage circuit 94 toward the high-voltage circuit 95, that is, the signal output from the low-voltage circuit 94, is, for example, a signal for driving the switching element 91. The signal is, for example, a pulse signal. Based on the signal received from the low-voltage circuit 94 through the transformer chip A1, the high-voltage circuit 95 generates a signal for driving the switching element 91 and applies the signal to the switching element 91. The switching element 91 is switched on and off in response to the signal applied from the high-voltage circuit 95.

In the transformer chip A1, the first coil 20 and the second coil 30 are insulated from each other. Thus, the transformer chip A1 insulates the low-voltage circuit 94 from the high-voltage circuit 95. More specifically, the transformer chip A1 interrupts transmission of a direct current voltage between the low-voltage circuit 94 and the high-voltage circuit 95. The transformer chip A1 allows transmission of a signal such as pulse signal between the low-voltage circuit 94 and the high-voltage circuit 95.

### Operation

Operation of the transformer chip A1 of the present embodiment will now be described.

The insulation voltage of the transformer chip A1 will now be described.

In the circuit shown in FIG. 7, the first coil 20 of the transformer chip A1 is connected to the ground GND1 of the low-voltage circuit 94. The second coil 30 of the transformer chip A1 is connected to the ground GND2 of the high-voltage circuit 95. The ground GND2 of the high-voltage circuit 95 is connected to a source terminal of the switching element 91 that is driven by the high-voltage circuit 95. Thus, the potential of one terminal of the second coil 30 equals the second reference potential. The second reference potential varies as the inverter device 90 is driven. The first coil 20 is connected to the ground GND1, which has the first reference potential. The insulation voltage between the first coil 20 and the second coil 30 needs to correspond to the varying second reference potential.

In the present embodiment, the transformer chip A1 includes the first coil 20 and the second coil 30 arranged on the substrate main surface 101 of the substrate 10. The first coil 20 and the second coil 30 are arranged next to each other in the first direction on the substrate main surface 101 of the substrate 10. The first coil 20 includes the first substrate wires 21 and the first connection wires 22 arranged next to each other in the X-direction. The first substrate wires 21 extend in a direction intersecting the X-direction. Each first connection wire 22 is connected between two of the first substrate wires 21 located adjacent to each other in the X-direction. The second coil 30 includes the second substrate wires 31 and the second connection wires 32 arranged next to each other in the X-direction. The second substrate wires 31 extend in a direction intersecting the X-direction. Each second connection wire 32 is connected between two of the second substrate wires 31 located adjacent to the each other in the X-direction.

The position of the first coil 20 is specified by the positions of the first substrate wires 21 and the first connection wires 22 formed on the substrate main surface 101 of the substrate 10. The position of the second coil 30 is specified by the positions of the second substrate wires 31 and the second connection wires 32 formed on the substrate main surface 101 of the substrate 10. The insulation voltage of the transformer chip A1 is determined by the distance between the first coil 20 and the second coil 30. That is, the insulation voltage of the transformer chip A1 is determined by the arrangement positions of the first coil 20 and the second coil 30. Thus, the transformer chip A1 readily obtains a desired property. In other words, the degree of design freedom in the transformer chip A1 is increased.

The insulation voltage of the transformer chip A1 is adjusted by changing the arrangement positions of the first coil 20 and the second coil 30. Thus, the property of the transformer chip A1 is readily changed without changing the steps in the manufacturing process such as adding a new step. This increases the degree of design freedom in the transformer chip A1.

The first coil 20 and the second coil 30 are formed by plating. More specifically, a mask that includes openings corresponding to the first substrate wires 21 of the first coil 20 and the second substrate wires 31 of the second coil 30 is formed, and a plating metal is deposited in the openings of the mask. The mask is formed by, for example, exposing and developing a photosensitive resist layer. Thus, the positions of the first coil 20 and the second coil 30 are changed by simply changing the positions of the openings in the mask. This increases the degree of design freedom in the transformer chip A1.

As shown in FIGS. 2 and 5, the first connection wires 22 and the first substrate wires 21 are alternately connected in the X-direction. One first connection wire 22 and one first substrate wire 21 form one coil part (one turn) of the first coil 20. In other words, one first connection wire 22 and one first substrate wire 21 form a unit element of one turn of the first coil 20. Thus, the number of the first substrate wires 21 and the number of the first connection wires 22 correspond to the number of turns in the first coil 20. This allows the number of turns in the first coil 20 to be readily changed by changing the number of the first substrate wires 21 and the number of the first connection wires 22 formed on the substrate 10. Thus, the degree of design freedom in the first coil 20 is increased.

As shown in FIGS. 2 and 5, the first substrate wires 21 extend in a direction intersecting the X-direction. The first substrate wires 21 and the first connection wires 22 each form one coil part (one turn) of the first coil 20. The length of one turn is specified by the length of the first substrate wire 21 and the length of the first connection wire 22. In the present embodiment, the first substrate wire 21 is formed on the substrate main surface 101. This allows the length of the first substrate wire 21 to be readily changed. Thus, the degree of design freedom in the first coil 20 is increased.

As shown in FIGS. 2 and 6, the second connection wires 32 and the second substrate wires 31 are alternately connected in the X-direction. One second connection wire 32 and one second substrate wire 31 form one coil part (one turn) of the second coil 30. In other words, one second connection wire 32 and one second substrate wire 31 form a unit element of one turn of the second coil 30. Thus, the number of the second substrate wires 31 and the number of the second connection wires 32 correspond to the number of turns in the second coil 30. This allows the number of turns in the second coil 30 to be readily changed by changing the number of the second substrate wires 31 and the number of the second connection wires 32 formed on the substrate 10. Thus, the degree of design freedom in the second coil 30 is increased.

As shown in FIGS. 2 and 5, the third ends 221 of the first connection wires 22 are connected to the first ends 211 of the first substrate wires 21, and the fourth ends 222 of the first connection wires 22 are connected to the second ends 212 of the first substrate wires 21. The length of the first connection wires 22 is readily changed in accordance with the length of the first substrate wires 21. Thus, the degree of design freedom in the first coil 20 is increased.

As shown in FIGS. 3 and 4, the first connection wires 22 are formed along a surface 601 of the insulation member 60. Thus, the length of the first connection wires 22 is specified by the cross-sectional shape of the insulation member 60 and the height of the insulation member 60. This allows the length of the first connection wires 22 to be readily changed by the shape of the insulation member 60. Thus, the degree of design freedom in the first coil 20 is increased.

As shown in FIG. 3, the second connection wires 32 are formed along the surface 601 of the insulation member 60. Thus, the length of the second connection wires 32 is specified by the cross-sectional shape of the insulation member 60 and the height of the insulation member 60. This allows the length of the second connection wires 32 to be readily changed by the shape of the insulation member 60. Thus, the degree of design freedom in the second coil 30 is increased.

The length of one turn in the first coil 20 is specified by the length of the first substrate wire 21 and the first connection wire 22. As shown in FIG. 4, as viewed in the X-direction, the length of one turn in the first coil 20 is specified by the cross-sectional shape of the insulation member 60. In other words, the length of one turn in the first coil 20 is readily changed by changing the size of the insulation member 60. The length of one turn in the second coil 30 is readily changed in the same manner as the first coil 20. Thus, in the transformer chip A1, the degree of design freedom for the length of one turn in the first coil 20 and the second coil 30 is increased.

In the first coil 20, the width W13 of the third end 221 is smaller than the width W11 of the first end 211. Thus, even when the third end 221 is formed in a position deviated in the X-direction due to a manufacturing error, the third end 221 is formed on the first end 211. The length L13 of the third end 221 is smaller than the length L11 of the first end 211. Thus, even when the third end 221 is formed in a position deviated in the Y-direction due to a manufacturing error, the third end 221 is formed on the first end 211.

In the first coil 20, the width W14 of the fourth end 222 is smaller than the width W12 of the second end 212. Thus, even when the fourth end 222 is formed in a position deviated in the X-direction due to a manufacturing error, the fourth end 222 is formed on the second end 212. The length L14 of the fourth end 222 is smaller than the length L12 of the second end 212. Thus, even when the fourth end 222 is formed in a position deviated in the Y-direction due to a manufacturing error, the fourth end 222 is formed on the second end 212.

In the second coil 30, the width W23 of the third end 321 is smaller than the width W21 of the first end 311. Thus, even when the third end 321 is formed in a position deviated in the X-direction due to a manufacturing error, the third end 321 is formed on the first end 311. The length L23 of the third end 321 is smaller than the length L21 of the first end 311. Thus, even when the third end 321 is formed in a position deviated in the Y-direction due to a manufacturing error, the third end 321 is formed on the first end 311.

In the second coil 30, the width W24 of the fourth end 322 is smaller than the width W22 of the second end 312. Thus, even when the fourth end 322 is formed in a position deviated in the X-direction due to a manufacturing error, the fourth end 322 is formed on the second end 312. The length L24 of the fourth end 322 is smaller than the length L22 of the second end 312. Thus, even when the fourth end 322 is formed in a position deviated in the Y-direction due to a manufacturing error, the fourth end 322 is formed on the second end 312.

In the Y-direction, the length L13 of the third end 221 of the first connection wire 22 is smaller than the length L11 of the first end 211 of the first substrate wire 21. In addition, the difference between the length L13 of the third end 221 and the length L11 of the first end 211 is greater than the difference between the width W13 of the third end 221 and the width W11 of the first end 211. That is, when the third end 221 is connected to the first end 211, the positional margin in the Y-direction is set to be greater than the positional margin in the X-direction. Positions of the third end 221 and the fourth end 222 in the Y-direction are affected by the size of the insulation member 60 and the formation position of the insulation member 60 in the Y-direction. Thus, the effect of the formation of the insulation member 60 is reduced. This ensures the connection of the first connection wire 22 to the first substrate wire 21.

In the Y-direction, the length L14 of the fourth end 222 of the first connection wire 22 is smaller than the length L12 of the second end 212 of the first substrate wire 21. In addition, the difference between the length L14 of the fourth end 222 and the length L12 of the second end 212 is greater than the difference between the width W13 of the fourth end 222 and the width W11 of the second end 212. That is, when the fourth end 222 is connected to the second end 212, the positional margin in the Y-direction is set to be greater than the positional margin in the X-direction. Positions of the fourth end 222 and the fourth end 222 in the Y-direction are affected by the size of the insulation member 60 and the formation position of the insulation member 60 in the Y-direction. Thus, the effect of the formation of the insulation member 60 is reduced. This ensures the connection of the first connection wire 22 to the first substrate wire 21.

In the Y-direction, the length L23 of the third end 321 of the second connection wire 32 is smaller than the length L21 of the first end 311 of the second substrate wire 31. In addition, the difference between the length L23 of the third end 321 and the length L21 of the first end 311 is greater than the difference between the width W13 of the third end 321 and the width W11 of the first end 311. That is, when the third end 321 is connected to the first end 311, the positional margin in the Y-direction is set to be greater than the positional margin in the X-direction. Positions of the third end 321 and the fourth end 322 in the Y-direction are affected by the size of the insulation member 60 and the formation position of the insulation member 60 in the Y-direction. Thus, the effect of the formation of the insulation member 60 is reduced. This ensures the connection of the second connection wire 32 to the second substrate wire 31.

In the Y-direction, the length L24 of the fourth end 322 of the second connection wire 32 is smaller than the length L22 of the second end 312 of the second substrate wire 31. In addition, the difference between the length L24 of the fourth end 322 and the length L22 of the second end 312 is greater than the difference between the width W13 of the fourth end 322 and the width W11 of the second end 312. That is, when the fourth end 322 is connected to the second end 312, the positional margin in the Y-direction is set to be greater than the positional margin in the Y-direction. Positions of the fourth end 322 and the fourth end 322 in the Y-direction are affected by the size of the insulation member 60 and the formation position of the insulation member 60 in the Y-direction. Thus, the effect of the formation of the insulation member 60 is reduced. This ensures the connection of the second connection wire 32 to the second substrate wire 31.

### Advantages

As described above, the present embodiment has the following advantages.

(1-1) In the present embodiment, the transformer chip A1 includes the first coil 20 and the second coil 30 arranged on the substrate main surface 101 of the substrate 10. The first coil 20 and the second coil 30 are arranged next to each other in the first direction on the substrate main surface 101 of the substrate 10. The first coil 20 includes the first substrate wires 21 and the first connection wires 22 arranged next to each other in the X-direction. The first substrate wires 21 extend in a direction intersecting the X-direction. Each first connection wire 22 is connected between two of the first substrate wires 21 located adjacent to each other in the X-direction. The second coil 30 includes the second substrate wires 31 and the second connection wires 32 arranged next to each other in the X-direction. The second substrate wires 31 extend in a direction intersecting the X-direction. Each second connection wire 32 is connected between two of the second substrate wires 31 located adjacent to the each other in the X-direction.

The position of the first coil 20 is specified by the positions of the first substrate wires 21 and the first connection wires 22 formed on the substrate main surface 101 of the substrate 10. The position of the second coil 30 is specified by the positions of the second substrate wires 31 and the second connection wires 32 formed on the substrate main surface 101 of the substrate 10. The insulation voltage of the transformer chip A1 is determined by the distance between the first coil 20 and the second coil 30. That is, the insulation voltage of the transformer chip A1 is determined by the arrangement positions of the first coil 20 and the second coil 30. Thus, the transformer chip A1 readily obtains a desired property. In other words, the degree of design freedom in the transformer chip A1 is increased.

(1-2) The insulation voltage of the transformer chip A1 is adjusted by changing the arrangement positions of the first coil 20 and the second coil 30. Thus, the property of the transformer chip A1 is readily changed without changing the steps in the manufacturing process such as adding a new step. This increases the degree of design freedom in the transformer chip A1.

(1-3) The first coil 20 and the second coil 30 are formed by plating. More specifically, a mask that includes openings corresponding to the first substrate wires 21 of the first coil 20 and the second substrate wires 31 of the second coil 30 is formed, and a plating metal is deposited in the openings of the mask. The mask is formed by, for example, exposing and developing a photosensitive resist layer. Thus, the positions of the first coil 20 and the second coil 30 are changed by simply changing the positions of the openings in the mask. This increases the degree of design freedom in the transformer chip A1.

(1-4) The first connection wires 22 and the first substrate wires 21 are alternately connected in the X-direction. One first connection wire 22 and one first substrate wire 21 form one coil part (one turn) of the first coil 20. In other words, one first connection wire 22 and one first substrate wire 21 form a unit element of one turn of the first coil 20. Thus, the number of the first substrate wires 21 and the number of the first connection wires 22 correspond to the number of turns in the first coil 20. This allows the number of turns in the first coil 20 to be readily changed by changing the number of the first substrate wires 21 and the number of the first connection wires 22 formed on the substrate 10. Thus, the degree of design freedom in the first coil 20 is increased.

(1-5) The first substrate wires 21 extend in a direction intersecting the X-direction. The first substrate wires 21 and the first connection wires 22 each form one coil part (one turn) of the first coil 20. The length of one turn is specified by the length of the first substrate wire 21 and the length of the first connection wire 22. In the present embodiment, the first substrate wire 21 is formed on the substrate main surface 101. This allows the length of the first substrate wire 21 to be readily changed. Thus, the degree of design freedom in the first coil 20 is increased.

(1-6) The second connection wires 32 and the second substrate wires 31 are alternately connected in the X-direction. One second connection wire 32 and one second substrate wire 31 form one coil part (one turn) of the second coil 30. In other words, one second connection wire 32 and one second substrate wire 31 form a unit element of one turn of the second coil 30. Thus, the number of the second substrate wires 31 and the number of the second connection wires 32 correspond to the number of turns in the second coil 30. This allows the number of turns in the second coil 30 to be readily changed by changing the number of the second substrate wires 31 and the number of the second connection wires 32 formed on the substrate 10. Thus, the degree of design freedom in the second coil 30 is increased.

(1-7) The third ends 221 of the first connection wires 22 are connected to the first ends 211 of the first substrate wires 21, and the fourth ends 222 of the first connection wires 22 are connected to the second ends 212 of the first substrate wires 21. The length of the first connection wires 22 is readily changed in accordance with the length of the first substrate wires 21. Thus, the degree of design freedom in the first coil 20 is increased.

(1-8) The first connection wires 22 are formed along a surface 601 of the insulation member 60. Thus, the length of the first connection wires 22 is specified by the cross-sectional shape of the insulation member 60 and the height of the insulation member 60. This allows the length of the first connection wires 22 to be readily changed by the shape of the insulation member 60. Thus, the degree of design freedom in the first coil 20 is increased.

(1-9) The second connection wires 32 are formed along the surface 601 of the insulation member 60. Thus, the length of the second connection wires 32 is specified by the cross-sectional shape of the insulation member 60 and the height of the insulation member 60. This allows the length of the second connection wires 32 to be readily changed by the shape of the insulation member 60. Thus, the degree of design freedom in the second coil 30 is increased.

(1-10) The length of one turn in the first coil 20 is specified by the length of the first substrate wire 21 and the first connection wire 22. As viewed in the X-direction, the length of one turn in the first coil 20 is specified by the cross-sectional shape of the insulation member 60. In other words, the length of one turn in the first coil 20 is readily changed by changing the size of the insulation member 60. The length of one turn in the second coil 30 is readily changed in the same manner as the first coil 20. Thus, in the transformer chip A1, the degree of design freedom for the length of one turn in the first coil 20 and the second coil 30 is increased.

(1-11) In the first coil 20, the width W13 of the third end 221 is smaller than the width W11 of the first end 211. Thus, even when the third end 221 is formed in a position deviated in the X-direction due to a manufacturing error, the third end 221 is formed on the first end 211. The length L13 of the third end 221 is smaller than the length L11 of the first end 211. Thus, even when the third end 221 is formed in a position deviated in the Y-direction due to a manufacturing error, the third end 221 is formed on the first end 211.

(1-12) In the first coil 20, the width W14 of the fourth end 222 is smaller than the width W12 of the second end 212. Thus, even when the fourth end 222 is formed in a position deviated in the X-direction due to a manufacturing error, the fourth end 222 is formed on the second end 212. A length L14 of the fourth end 222 is smaller than a length L12 of the second end 212. Thus, even when the fourth end 222 is formed in a position deviated in the Y-direction due to a manufacturing error, the fourth end 222 is formed on the second end 212.

(1-13) In the second coil 30, the width W23 of the third end 321 is smaller than the width W21 of the first end 311. Thus, even when the third end 321 is formed in a position deviated in the X-direction due to a manufacturing error, the third end 321 is formed on the first end 311. The length L23 of the third end 321 is smaller than the length L21 of the first end 311. Thus, even when the third end 321 is formed in a position deviated in the Y-direction due to a manufacturing error, the third end 321 is formed on the first end 311.

(1-14) In the second coil 30, the width W24 of the fourth end 322 is smaller than the width W22 of the second end 312. Thus, even when the fourth end 322 is formed in a position deviated in the X-direction due to a manufacturing error, the fourth end 322 is formed on the second end 312. A length L24 of the fourth end 322 is smaller than a length L22 of the second end 312. Thus, even when the fourth end 322 is formed in a position deviated in the Y-direction due to a manufacturing error, the fourth end 322 is formed on the second end 312.

(1-15) In the Y-direction, the length L13 of the third end 221 of the first connection wire 22 is smaller than the length L11 of the first end 211 of the first substrate wire 21. In addition, the difference between the length L13 of the third end 221 and the length L11 of the first end 211 is greater than the difference between the width W13 of the third end 221 and the width W11 of the first end 211. That is, when the third end 221 is connected to the first end 211, the positional margin in the Y-direction is set to be greater than the positional margin in the X-direction. Positions of the third end 221 and the fourth end 222 in the Y-direction are affected by the size of the insulation member 60 and the formation position of the insulation member 60 in the Y-direction. Thus, the effect of the formation of the insulation member 60 is reduced. This ensures the connection of the first connection wire 22 to the first substrate wire 21.

(1-16) In the Y-direction, the length L14 of the fourth end 222 of the first connection wire 22 is smaller than the length L12 of the second end 212 of the first substrate wire 21. In addition, the difference between the length L14 of the fourth end 222 and the length L12 of the second end 212 is greater than the difference between the width W13 of the fourth end 222 and the width W11 of the second end 212. That is, when the fourth end 222 is connected to the second end 212, the positional margin in the Y-direction is set to be greater than the positional margin in the X-direction. Positions of the fourth end 222 and the fourth end 222 in the Y-direction are affected by the size of the insulation member 60 and the formation position of the insulation member 60 in the Y-direction. Thus, the effect of the formation of the insulation member 60 is reduced. This ensures the connection of the first connection wire 22 to the first substrate wire 21.

(1-17) In the Y-direction, the length L23 of the third end 321 of the second connection wire 32 is smaller than the length L21 of the first end 311 of the second substrate wire 31. In addition, the difference between the length L23 of the third end 321 and the length L21 of the first end 311 is greater than the difference between the width W13 of the third end 321 and the width W11 of the first end 311. That is, when the third end 321 is connected to the first end 311, the positional margin in the Y-direction is set to be greater than the positional margin in the X-direction. Positions of the third end 321 and the fourth end 322 in the Y-direction are affected by the size of the insulation member 60 and the formation position of the insulation member 60 in the Y-direction. Thus, the effect of the formation of the insulation member 60 is reduced. This ensures the connection of the second connection wire 32 to the second substrate wire 31.

(1-18) In the Y-direction, the length L24 of the fourth end 322 of the second connection wire 32 is smaller than the length L22 of the second end 312 of the second substrate wire 31. In addition, the difference between the length L24 of the fourth end 322 and the length L22 of the second end 312 is greater than the difference between the width W13 of the fourth end 322 and the width W11 of the second end 312. That is, when the fourth end 322 is connected to the second end 312, the positional margin in the Y-direction is set to be greater than the positional margin in the Y-direction. Positions of the fourth end 322 and the fourth end 322 in the Y-direction are affected by the size of the insulation member 60 and the formation position of the insulation member 60 in the Y-direction. Thus, the effect of the formation of the insulation member 60 is reduced. This ensures the connection of the second connection wire 32 to the second substrate wire 31.

### Second Embodiment

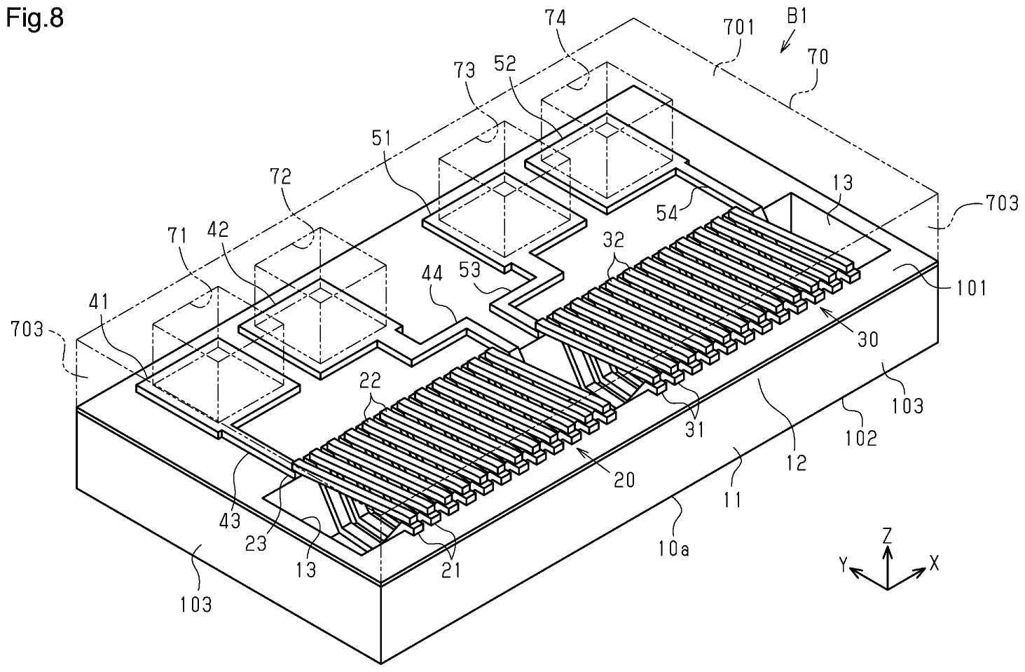

A second embodiment of a transformer chip B1 will now be described with reference to FIGS. 8 to 11.

In the description hereafter, same reference characters are given to those components that are the same as the corresponding components of the transformer chip A1 in the first embodiment. Such components will not be described in detail.

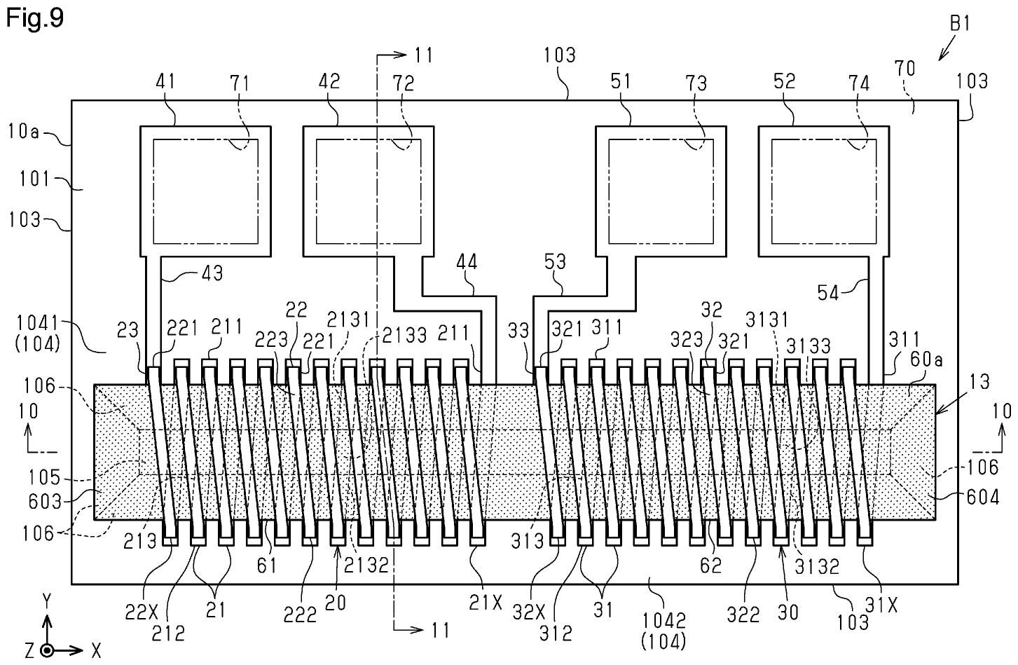

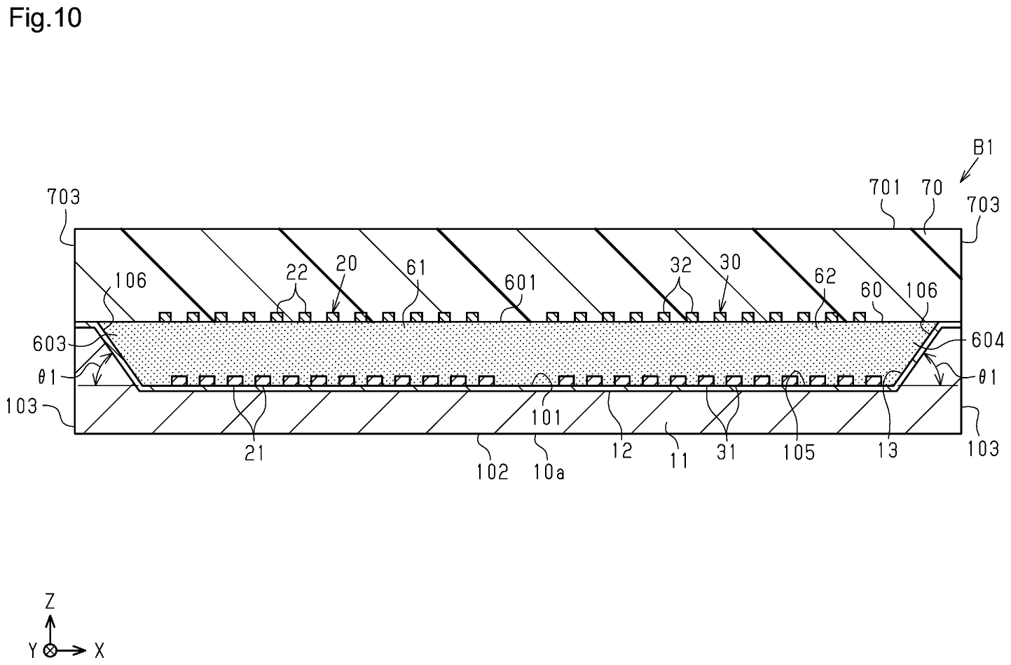

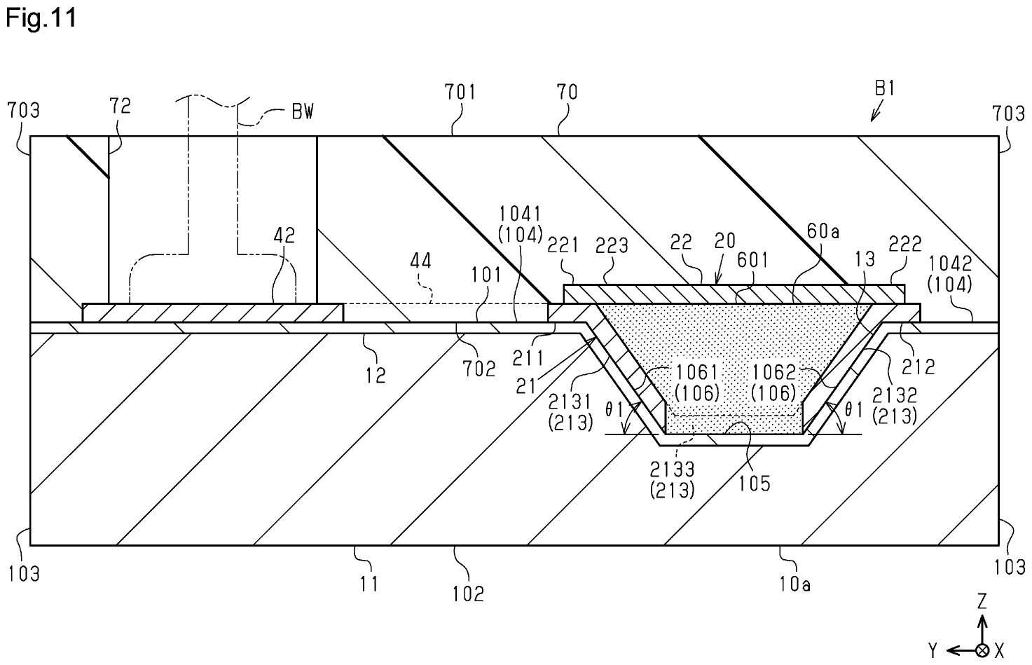

FIG. 8 is a perspective view of the transformer chip B1. FIG. 9 is a plan view of the transformer chip B1. FIG. 10 is a cross-sectional view taken along line 10-10 in FIG. 9. FIG. 11 is a cross-sectional view taken along line 11-11 in FIG. 9.

As shown in FIGS. 8 to 11, the transformer chip B1 includes a substrate 10a, the first coil 20, the second coil 30, the input pads 41 and 42, the output pads 51 and 52, an insulation member 60a, and the encapsulation resin 70.

### Substrate

As shown in FIGS. 8 to 12, the substrate 10a of the present embodiment includes a recess 13 in the substrate main surface 101. As shown in FIGS. 10 and 11, the recess 13 is recessed toward the substrate back surface 102. The recess 13 is rectangular as viewed in the Z-direction. The substrate main surface 101, including the recess 13, includes an upper surface 104 having the form of a frame extending around the recess 13. As shown in FIG. 9, the upper surface 104 includes a first upper surface 1041 and a second upper surface 1042 located at opposite sides of the recess 13 in the Y-direction. The input pads 41 and 42, which are connected to the first coil 20, and the output pads 51 and 52, which are connected to the second coil 30, are mounted on the first upper surface 1041.

The recess 13 is formed by a bottom surface 105 and intermediate surfaces 106 located between the bottom surface 105 and the upper surface 104. The substrate 10a includes the bottom surface 105 and the intermediate surfaces 106 forming the recess 13. The recess 13 and the intermediate surfaces 106 are included in the substrate main surface 101. More specifically, in the present embodiment, the substrate main surface 101 includes the bottom surface 105 and the intermediate surfaces 106, which form the recess 13, and the upper surface 104 extending around the recess 13. The intermediate surfaces 106 include a first intermediate surface 1061 located between the bottom surface 105 and the first upper surface 1041 and a second intermediate surface 1062 located between the bottom surface 105 and the second upper surface 1042.

As shown in FIG. 9, the bottom surface 105 is rectangular and is elongated in the X-direction.

As shown in FIG. 10, the intermediate surfaces 106 are located at opposite sides of the bottom surface 105 in the X-direction. The two intermediate surfaces 106 are inclined so as to separate away from each other from the bottom surface 105 toward the upper surface 104.

As shown in FIG. 11, the intermediate surfaces 106 (1061, 1062) are located at opposite sides of the bottom surface 105 in the Y-direction. The two intermediate surfaces 1061 and 1062 are inclined so as to separate away from each other from the bottom surface 105 toward the upper surface 104.

The substrate 10a includes the substrate body 11 and the insulation film 12. The substrate body 11 is composed of a semiconductor substrate. The insulation film 12 is an electrically insulating film.

The substrate body 11 is formed from a semiconductor material that is a single-crystal material. In the present embodiment, the substrate body 11 is a Si substrate. The insulation film 12 is formed from SiO₂. The recess 13 is formed by performing etching (anisotropic etching) on the substrate body 11. The insulation film 12 is formed by, for example, thermally oxidizing the substrate body 11 that includes a recess. Alternatively, the insulation film 12 maybe formed from, for example, silicon nitride (SiN), aluminum nitride (AlN), or the like.

The upper surface 104 of the substrate 10a is a surface in a plane direction based on a Si crystal structure and, in the present embodiment, is the (100) plane. The intermediate surface 106 is the {111} plane. Thus, as shown in FIGS. 10 and 11, an inclination angle θ1 of the intermediate surface 106 from the bottom surface 105 is based on the crystal structure of the Si substrate and is approximately 54.7°.

### First Coil, Second Coil, and Insulation Member

As shown in FIGS. 8 to 10, the first coil 20 and the second coil 30 are arranged on the substrate main surface 101 of the substrate 10a. The first coil 20 and the second coil 30 are arranged on the substrate main surface 101 along the substrate main surface 101. In the present embodiment, the first coil 20 and the second coil 30 are arranged next to each other in the X-direction on the substrate main surface 101.

The first coil 20 includes the first substrate wires 21 and the first connection wires 22. The first substrate wires 21 and the first connection wires 22 are formed from, for example, a conductive metal such as copper (Cu) or a Cu alloy.

As shown in FIGS. 8 to 10, the first substrate wires 21 are arranged on the substrate main surface 101 of the substrate 10a. As shown in FIG. 9, the first substrate wires 21 are arranged next to each other in the X-direction. The first substrate wires 21 extend in a direction intersecting the X-direction.

As shown in FIGS. 9 to 11, each of the first substrate wires 21 includes the first end 211, the second end 212 opposite to the first end 211, and the first conductor 213 located between the first end 211 and the second end 212. The first coil 20 includes the first connector 23.

As shown in FIGS. 10 and 11, the first substrate wires 21 extend along the surface of the recess 13.

As shown in FIGS. 9 and 11, the recess 13 is formed by the bottom surface 105 and the intermediate surfaces 106 (1061, 1062), which are located at opposite sides of the bottom surface 105. The substrate main surface 101 includes the first upper surface 1041, the second upper surface 1042, and a surface of the recess 13. The recess 13 includes the bottom surface 105 and the intermediate surfaces 1061 and 1062. Each first substrate wire 21 is in contact with the first upper surface 1041, the intermediate surface 1061, the bottom surface 105, the intermediate surface 1062, and the second upper surface 1042. The first end 211 of the first substrate wire 21 is located on the first upper surface 1041. The second end 212 of the first substrate wire 21 is located on the second upper surface 1042. The first conductor 213, which is located between the first end 211 and the second end 212, is in contact with the intermediate surface 1061, the bottom surface 105, and the intermediate surface 1062. In the present embodiment, the first conductor 213 includes a bottom portion 2133 in contact with the bottom surface 105 and side portions 2131 and 2132 in contact with the intermediate surfaces 1061 and 1062.

As shown in FIG. 10, the insulation member 60a is formed to fill the recess 13. As shown in FIGS. 9 and 10, the insulation member 60a is formed to extend through the first coil 20 and the second coil 30. More specifically, the insulation member 60a includes a first end 603 projecting from the first coil 20 in a direction away from the second coil 30 and a second end 604 projecting from the second coil 30 in a direction away from the first coil 20.

The insulation member 60a includes a first part 61 corresponding to the first coil 20 and a second part 62 corresponding to the second coil 30. As shown in FIG. 10, the first part 61 is located between the first substrate wire 21 and the first connection wire 22 of the first coil 20. The second part 62 is located between the second substrate wires 31 and the second connection wires 32 of the second coil 30.

As shown in FIGS. 9 and 11, the insulation member 60a is formed to cover the first substrate wires 21. As shown in FIG. 11, the insulation member 60a is formed to expose the first end 211 and the second end 212 of the first substrate wire 21 and cover the first conductor 213. In the present embodiment, the surface 601 of the insulation member 60a is planar.

As shown in FIGS. 8 to 10, the first connection wires 22 are arranged next to each other in the X-direction. The first connection wires 22 extend in a direction intersecting the X-direction.

As shown in FIG. 10, the first connection wires 22 are in contact with the insulation member 60a. The first connection wires 22 extend along the surface 601 of the insulation member 60a. As shown in FIG. 9, each of the first connection wires 22 is located adjacent to two of the first substrate wires 21 in the X-direction and connects the first end 211 of one of the two of the first substrate wires 21 and the second end 212 of the other one of the two of the first substrate wires 21.

As shown in FIGS. 9 and 11, in the present embodiment, each of the first connection wires 22 includes the third end 221, the fourth end 222 opposite to the third end 221, and the second conductor 223 located between the third end 221 and the fourth end 222.

The third end 221 of the first connection wire 22 is connected to the first end 211 of the first substrate wire 21. The fourth end 222 of the first connection wire 22 is connected to the second end 212 of the first substrate wire 21. The second conductor 223 connects the third end 221 and the fourth end 222.

The first end 211 of the first substrate wire 21X, which is one of the first substrate wires 21 located at the end close to the second coil 30, is not connected to the first connection wires 22. In the present embodiment, the third end 221 of the first connection wire 22X, which is one of the first connection wires 22 located at the end opposite from the second coil 30, is connected to the first connector 23 of the first coil 20.

The second coil 30 includes the second substrate wires 31 and the second connection wires 32. The second substrate wires 31 and the second connection wires 32 are formed from, for example, a conductive metal such as copper (Cu) or a Cu alloy.

As shown in FIGS. 8 to 10, the second substrate wires 31 are arranged on the substrate main surface 101 of the substrate 10a. As shown in FIG. 9, the second substrate wires 31 are arranged next to each other in the X-direction. The second substrate wires 31 extend in a direction intersecting the X-direction.

As shown in FIGS. 8 to 10, the second substrate wires 31 are arranged on the substrate main surface 101 of the substrate 10a. As shown in FIG. 9, the second substrate wires 31 are arranged next to each other in the X-direction. The second substrate wires 31 extend in a direction intersecting the X-direction.

As shown in FIGS. 9 to 11, each of the second substrate wires 31 includes the first end 311, the second end 312 opposite to the first end 311, and the first conductor 313 located between the first end 311 and the second end 312. The second coil 30 includes the second connector 33.

As shown in FIGS. 10 and 11, the second substrate wires 31 extend along the surface of the recess 13. As shown in FIG. 9, the recess 13 is formed by the bottom surface 105 and the intermediate surfaces 106 (1061, 1062), which are located at opposite sides of the bottom surface 105. The substrate main surface 101 includes the first upper surface 1041, the second upper surface 1042, and a surface of the recess 13. The recess 13 includes the bottom surface 105 and the intermediate surfaces 1061 and 1062. Each second substrate wire 31 is in contact with the first upper surface 1041, the intermediate surface 1061, the bottom surface 105, the intermediate surface 1062, and the second upper surface 1042. The first end 311 of the second substrate wire 31 is located on the first upper surface 1041. The second end 312 of the second substrate wire 31 is located on the second upper surface 1042. The first conductor 313, which is located between the first end 311 and the second end 312, is in contact with the intermediate surface 1061, the bottom surface 105, and the intermediate surface 1062. In the present embodiment, the first conductor 313 includes a bottom portion 3133 in contact with the bottom surface 105 and side portions 3131 and 3132 in contact with the intermediate surfaces 1061 and 1062.

As shown in FIGS. 9 and 10, the insulation member 60a is formed to cover the second substrate wires 31. As shown in FIG. 9, the insulation member 60a is formed to expose the first ends 311 and the second ends 312 of the second substrate wires 31 and cover the first conductors 313.

As shown in FIGS. 8 to 10, the second connection wires 32 are arranged next to each other in the X-direction. The second connection wires 32 extend in a direction intersecting the X-direction.

As shown in FIG. 10, the second connection wires 32 are in contact with the insulation member 60a. The second connection wires 32 extend along the surface 601 of the insulation member 60a. As shown in FIG. 9, each of the second connection wires 32 is located adjacent to two of the second substrate wires 31 in the X-direction and connects the first end 311 of one of the two of the second substrate wires 31 and the second end 312 of the other one of the two of the second substrate wires 31.

As shown in FIG. 9, in the present embodiment, each second connection wire 32 includes a third end 321, a fourth end 322 opposite to the third end 321, and a second conductor 323 located between the third end 321 and the fourth end 322.

The third end 321 of the second connection wire 32 is connected to the first end 311 of the second substrate wire 31. The fourth end 322 of the second connection wire 32 is connected to the second end 312 of the second substrate wire 31. The second conductor 323 connects the third end 321 and the fourth end 322.

In the present embodiment, one of the second substrate wires 31 located at an end opposite from the first coil 20 is referred to as a second substrate wire 31X. The first end 311 of the second substrate wire 31X is not connected to the second connection wires 32. In the present embodiment, one of the second connection wires 32 located at the end close to the first coil 20 is referred to as a second connection wire 32X. The third end 321 of the second connection wire 32X is connected to the second connector 33 of the second coil 30.

### Operation

Operation of the transformer chip B1 of the present embodiment will now be described.

In the transformer chip B1 of the present embodiment, the substrate 10a includes the recess 13. The insulation member 60a is formed to fill the recess 13. Thus, the position of the insulation member 60a is determined by the position of the recess 13 in the substrate 10a. This structure increases the positional accuracy of the insulation member 60a as compared to a structure in which the insulation member 60a is formed on a flat surface. The formation of the insulation member 60a in a manner filing the recess 13 reduces the effect of the insulation member 60a on the positions of the first connection wires 22 of the first coil 20 and the second connection wires 32 of the second coil 30. This increases the degree of design freedom for the width and the length of the first coil 20 and the second coil 30.

In addition, in the first coil 20, the first connection wires 22 are further assuredly connected to the first substrate wires 21. Also, in the second coil 30, the second connection wires 32 are further assuredly connected to the second substrate wires 31.

The first connection wires 22 of the first coil 20 extend along the surface 601 of the insulation member 60a filling the recess 13 in the substrate 10a. In the same manner, the second connection wires 32 of the second coil 30 extend along the surface 601 of the insulation member 60a filling the recess 13 in the substrate 10a. This reduces the thickness of the encapsulation resin 70, which encapsulates the first coil 20 and the second coil 30, as compared to the first embodiment.

The first substrate wires 21 of the first coil 20 extend along the intermediate surface 1061, the bottom surface 105, and the intermediate surface 1062, which are the wall surfaces of the recess 13. In the same manner, the second substrate wires 31 of the second coil 30 extend along the intermediate surface 1061, the bottom surface 105, and the intermediate surface 1062, which are the wall surfaces of the recess 13. Therefore, the length of the first substrate wires 21 and the second substrate wires 31 is set by the depth of the recess 13, which is the distance from the substrate main surface 101 of the substrate 10a to the bottom surface 105 of the recess 13 in the Z-direction. The length of the first substrate wires 21 and the second substrate wires 31 and the length of the first connection wires 22 and the second connection wires 32 are set by the opening width of the recess 13 in the Y-direction. Thus, the depth of the recess 13 and the length of one turn in the first coil 20 and the second coil 30 are adjusted.

### Advantages

As described above, the present embodiment has the following advantages. (2-1) The same advantages as (1-1) to (1-7) and (1-11) to (1-14) of the first embodiment are obtained.

(2-2) In the transformer chip B1 of the present embodiment, the substrate 10a includes the recess 13. The insulation member 60a is formed to fill the recess 13. Thus, the position of the insulation member 60a is determined by the position of the recess 13 in the substrate 10a. This structure increases the positional accuracy of the insulation member 60a as compared to a structure in which the insulation member 60a is formed on a flat surface. The formation of the insulation member 60a in a manner filing the recess 13 reduces the effect of the insulation member 60a on the positions of the first connection wires 22 of the first coil 20 and the second connection wires 32 of the second coil 30. This increases the degree of design freedom for the width and the length of the first coil 20 and the second coil 30.

(2-3) In the transformer chip B1 of the present embodiment, the effect of the insulation member 60a on the positions of the first connection wires 22 of the first coil 20 and the second connection wires 32 of the second coil 30 is reduced. In the first coil 20, the first connection wires 22 are further assuredly connected to the first substrate wires 21. Also, in the second coil 30, the second connection wires 32 are further assuredly connected to the second substrate wires 31.

(2-4) The first connection wires 22 of the first coil 20 extend along the surface 601 of the insulation member 60a filling the recess 13 in the substrate 10a. In the same manner, the second connection wires 32 of the second coil 30 extend along the surface 601 of the insulation member 60a filling the recess 13 in the substrate 10a. This reduces the thickness of the encapsulation resin 70, which encapsulates the first coil 20 and the second coil 30, as compared to the first embodiment.

(2-5) The first substrate wires 21 of the first coil 20 extend along the intermediate surface 1061, the bottom surface 105, and the intermediate surface 1062, which are the wall surfaces of the recess 13. In the same manner, the second substrate wires 31 of the second coil 30 extend along the intermediate surface 1061, the bottom surface 105, and the intermediate surface 1062, which are the wall surfaces of the recess 13. Therefore, the length of the first substrate wires 21 and the second substrate wires 31 is set by the depth of the recess 13, which is the distance from the substrate main surface 101 of the substrate 10a to the bottom surface 105 of the recess 13 in the Z-direction. The length of the first substrate wires 21 and the second substrate wires 31 and the length of the first connection wires 22 and the second connection wires 32 are set by the opening width of the recess 13 in the Y-direction. Thus, the depth of the recess 13 and the length of one turn in the first coil 20 and the second coil 30 are adjusted.

### Third Embodiment

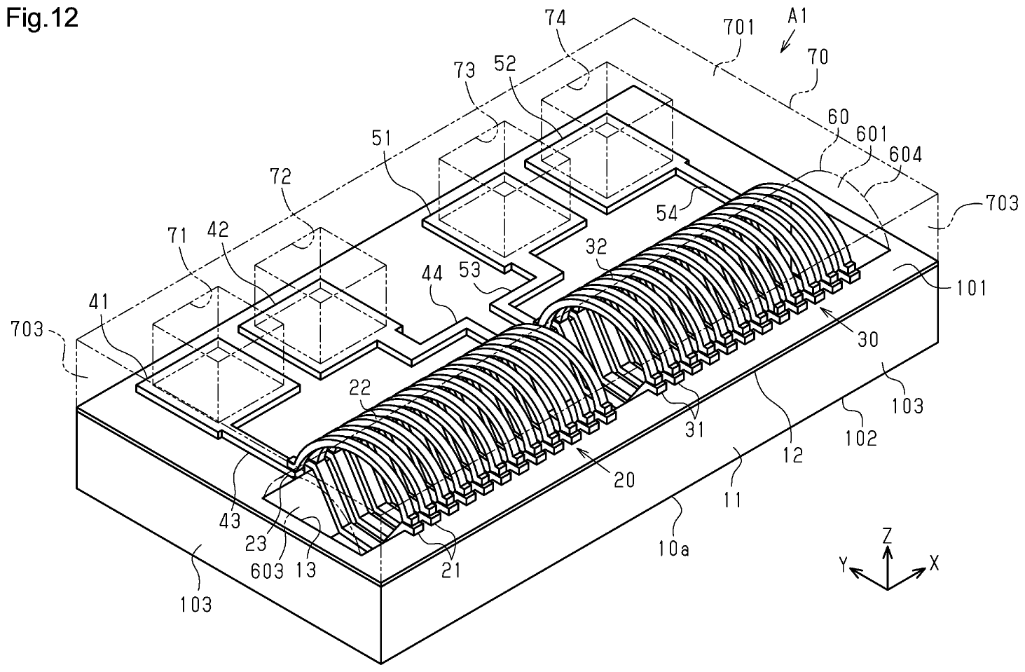

A third embodiment of a transformer chip C1 will now be described with reference to FIGS. 12 to 15.

In the transformer chip C1 of the present embodiment, the same reference characters are given to those components that are the same as the corresponding components of the transformer chip A1 of the first embodiment and the transformer chip B1 of the second embodiment. Such components will not be described in detail.

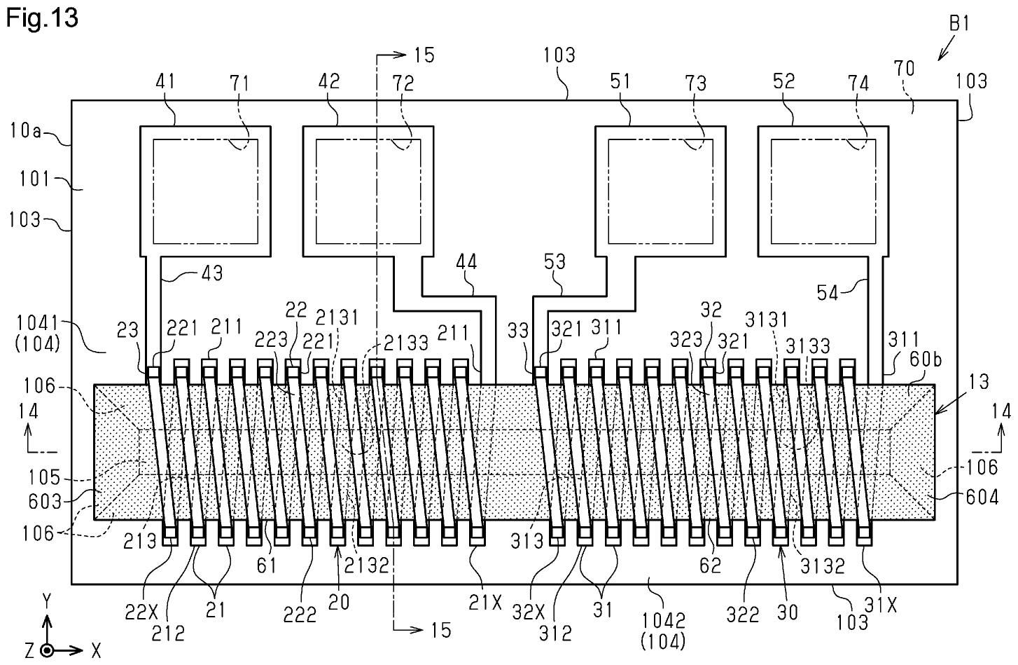

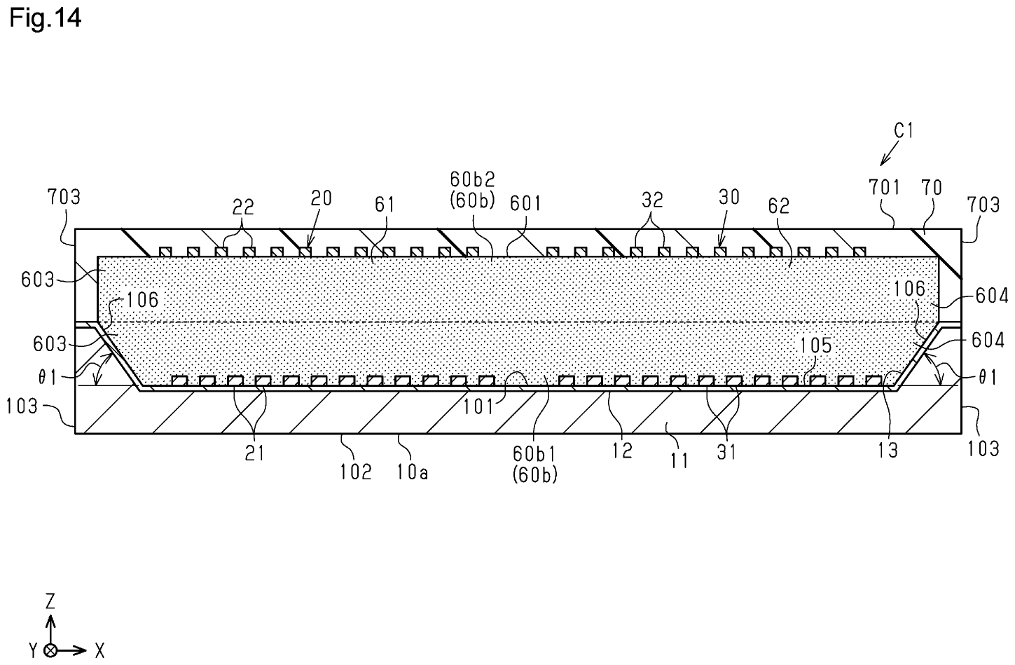

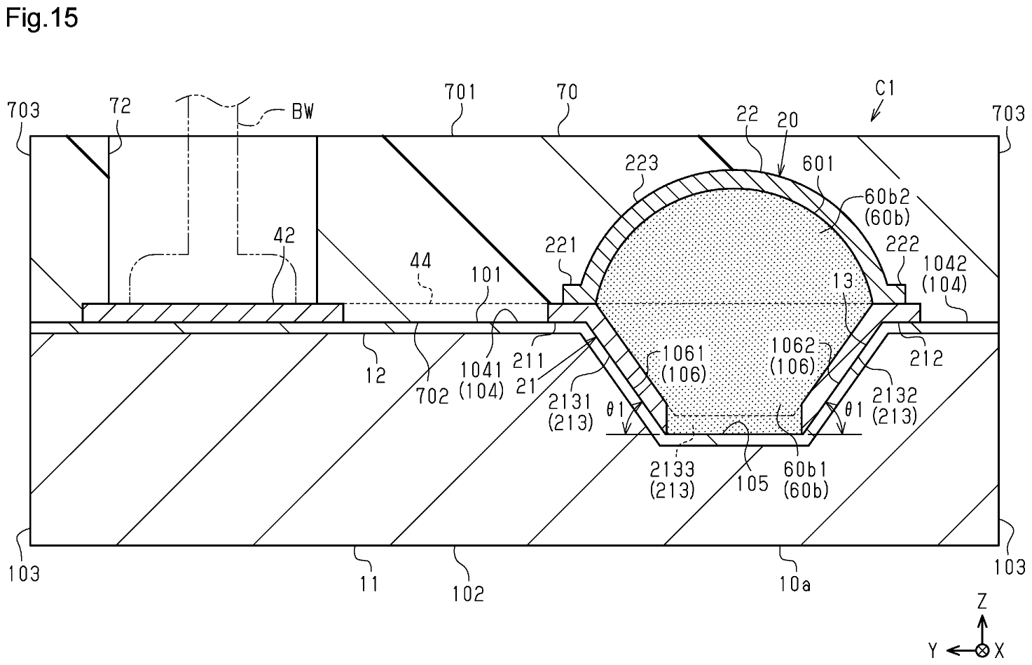

FIG. 12 is a perspective view of the transformer chip C1. FIG. 13 is a plan view of the transformer chip C1. FIG. 14 is a cross-sectional view taken along line 14-14 in FIG. 13. FIG. 15 is a cross-sectional view taken along line 15-15 in FIG. 13.

As shown in FIG. 12, the transformer chip C1 includes the substrate 10a, the first coil 20, the second coil 30, the input pads 41 and 42, the output pads 51 and 52, an insulation member 60b, and the encapsulation resin 70.

The transformer chip C1 of the present embodiment includes the substrate 10a of the second embodiment. That is, in the present embodiment, the substrate 10a includes the recess 13.

The first coil 20 includes the first substrate wires 21 arranged on the substrate main surface 101 of the substrate 10a. The second coil 30 includes the second substrate wires 31 arranged on the substrate main surface 101 of the substrate 10a.

As shown in FIGS. 13 and 14, the insulation member 60b covers the first substrate wires 21 of the first coil 20 and the second substrate wires 31 of the second coil 30. The insulation member 60b is formed from, for example, a phenol resin or a polyimide resin.

As shown in FIGS. 14 and 15, the insulation member 60b is formed to fill the recess 13 and project from the substrate main surface 101 in a direction away from the substrate back surface 102. In the present embodiment, the insulation member 60b includes a first insulation portion 60b1 filling the recess 13 and a second insulation portion 60b2 projecting from the first insulation portion 60b1 in a direction away from the substrate back surface 102. In an example, in the same manner as the insulation member 60 of the first embodiment, in a plane (YZ-plane) orthogonal to the X-direction, the second insulation portion 60b2 has an arcuate cross section that is bulged in a direction away from the substrate main surface 101.

As shown in FIG. 13, the second substrate wires 31 of the second coil 30 are formed from the first upper surface 1041 toward the second upper surface 1042 along the intermediate surface 1061, the bottom surface 105, and the intermediate surface 1062, which form the wall surfaces of the recess 13.

As shown in FIG. 14, the second connection wires 32 of the second coil 30 are in contact with the surface 601 of the insulation member 60b and, in a plane orthogonal to the X-direction, has a cross section extending along the arcuate surface of the insulation member 60b. The insulation member 60b separates a central part of the second connection wire 32 away from the second substrate wire 31 in the Z-direction.

### Operation

Operation of the transformer chip C1 of the present embodiment will now be described.

As viewed in the X-direction, the first coil 20 is greater in size than those of the first and second embodiments. The second coil 30 is configured in the same manner as the first coil 20. Thus, in the transformer chip C1 of the present embodiment, as viewed in the X-direction, the diameter of each of the first coil 20 and the second coil 30 is increased. When the number of turns in the first coil 20 is the same as those in the first and second embodiments, the first substrate wires 21 and the first connection wires 22, which form the first coil 20, are greater in length than those of the first and second embodiments. Thus, the length of the first coil 20 is increased. In the same manner as the first coil 20, the length of the second coil 30 is increased.

### Advantages

As described above, the present embodiment has the following advantages.

(3-1) The same advantages as shown in the first embodiment are obtained.

(3-2) The same advantages as (2-2) and (2-3) of the second embodiment are obtained.

(3-3) The first coil 20 is greater in size than those in the first and second embodiments as viewed in the X-direction. The second coil 30 is configured in the same manner as the first coil 20. Thus, in the transformer chip C1 of the present embodiment, as viewed in the X-direction, the diameter of each of the first coil 20 and the second coil 30 is increased.

(3-4) When the number of turns in the first coil 20 is the same as those in the first and second embodiments, the first substrate wires 21 and the first connection wires 22, which form the first coil 20, are greater in length than those of the first and second embodiments. Thus, the length of the first coil 20 is increased. In the same manner as the first coil 20, the length of the second coil 30 is increased.

### Modified Examples

The embodiments may be modified, for example, as follows. The embodiments described above and modified examples described below may be combined with one another as long as there is no technical inconsistency. In the following modified examples, the same reference characters are given to those elements that are the same as the corresponding elements of the above embodiments. Such elements will not be described in detail.

In the first embodiment, the shape of the insulation member 60 maybe changed.

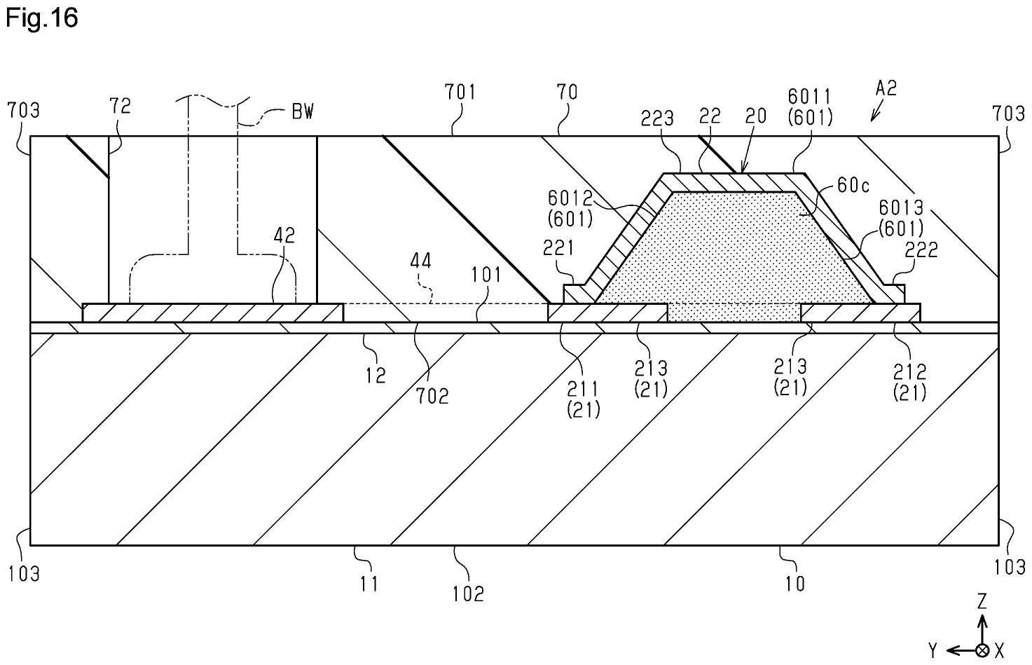

FIG. 16 is a diagram showing a modified example of a transformer chip A2. The transformer chip A2 includes an insulation member 60c having a quadrilateral cross section. The cross-sectional shape of the insulation member 60c is trapezoidal such that the length in the Y-direction is gradually decreased as the substrate main surface 101 becomes further. Thus, the surface 601 of the insulation member 60c includes an upper surface 6011 and side surfaces 6012 and 6013 inclined to face the Z-direction with respect to the Y-direction. The first connection wires 22 of the first coil 20 are formed along the side surface 6012, the upper surface 6011, and the side surface 6013. Although not shown, the second connection wires 32 of the second coil 30 are formed along the side surface 6012, the upper surface 6011, and the side surface 6013 in the same manner as the first connection wires 22 of the first coil 20. The transformer chip A2 including the insulation member 60c having the shape described above obtains the same advantages as the first embodiment of the transformer chip A1.

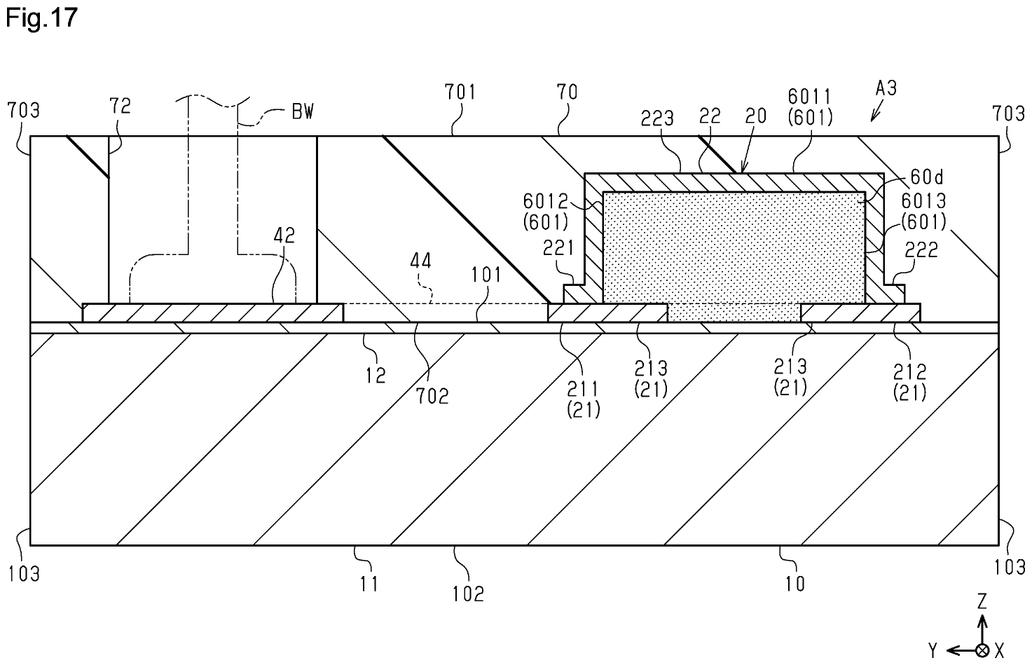

FIG. 17 is a diagram showing a modified example of a transformer chip A3. The transformer chip A3 includes an insulation member 60d having a quadrilateral cross section. The cross-section of the insulation member 60d is rectangular. Hence, the surface 601 of the insulation member 60d includes the upper surface 6011 and the side surfaces 6012 and 6013 facing in the Y-direction. The first connection wires 22 of the first coil 20 are formed along the side surface 6012, the upper surface 6011, and the side surface 6013. Although not shown, the second connection wires 32 of the second coil 30 are formed along the side surface 6012, the upper surface 6011, and the side surface 6013 in the same manner as the first connection wires 22 of the first coil 20. The transformer chip A3 including the insulation member 60d having the shape described above obtains the same advantages as the first embodiment of the transformer chip A1.

The cross-sectional shape of the insulation member 60 is not limited to the insulation member 60 of the first embodiment and the insulation members 60c and 60d of the modified examples. In an example, as viewed in the X-direction, the plane of the insulation member may have a cross-sectional shape having a linear part and a curved part (arcuate part).

In the insulation member 60b of the transformer chip C1 in the third embodiment shown in FIG. 15, the second insulation portion 60b2, which is the upper side projecting from the substrate main surface 101, may have the same cross-sectional shape as the insulation member 60c shown in FIG. 16. Alternatively, the second insulation portion 60b2 may have the same cross-sectional shape as the insulation member 60d shown in FIG. 17. Alternatively, for example, as viewed in the X-direction, the plane of the insulation member 60b may have a cross-sectional shape having a linear part and a curved part (arcuate part).

In the above embodiments, the number of turns in the first coil 20 and the second coil 30 maybe changed.

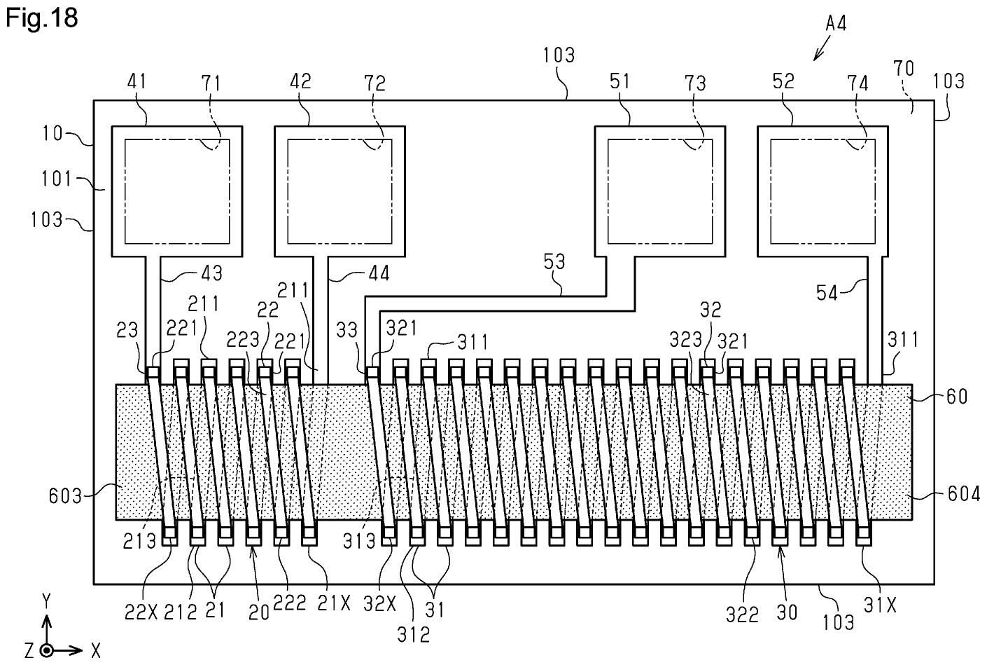

FIG. 18 is a diagram showing a modified example of a transformer chip A4. In the transformer chip A4, the second coil 30 is greater than the first coil 20 in number of turns. More specifically, the number of the second substrate wires 31 and the second connection wires 32 in the second coil 30 is greater than the number of the first substrate wires 21 and the first connection wires 22 in the first coil 20. In the transformer chip A4, in accordance with the ratio of the number of turns in the first coil 20 to the number of turns in the second coil 30, the amplitude of an input signal applied to the input pads 41 and 42 is changed, and an output signal having the changed amplitude is obtained from the output pads 51 and 52.

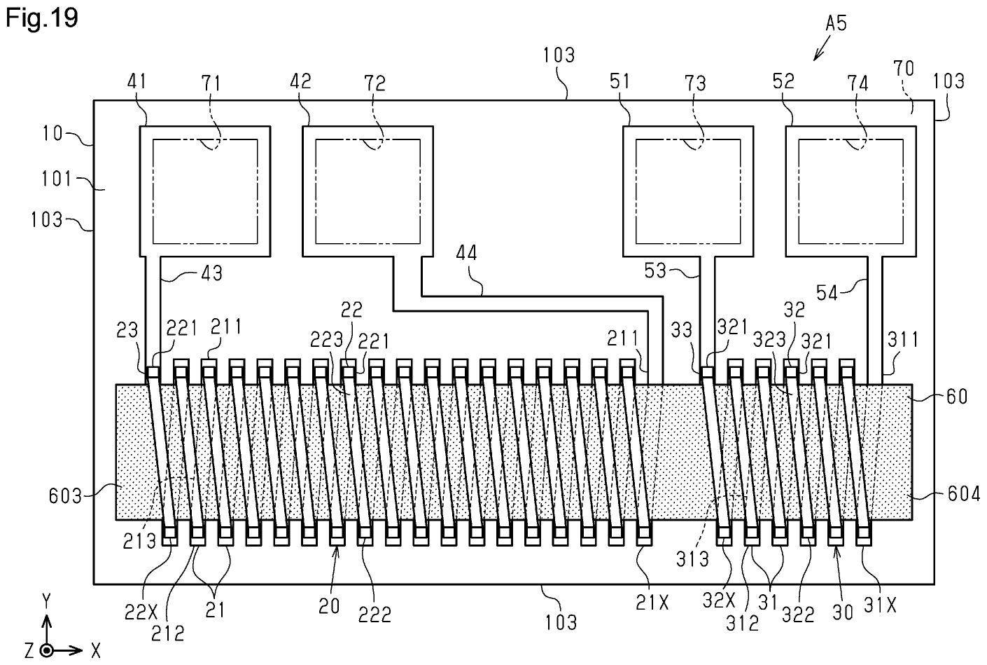

FIG. 19 is a diagram showing a modified example of a transformer chip A5. In the transformer chip A5, the number of turns in the first coil 20 is greater than the number of turns in the second coil 30. More specifically, the number of the first substrate wires 21 and the first connection wires 22 in the first coil 20 is greater than the number of the second substrate wires 31 and the second connection wires 32 in the second coil 30. In the transformer chip A5, in accordance with the ratio of the number of turns in the first coil 20 to the number of turns in the second coil 30, the amplitude of an input signal applied to the input pads 41 and 42 is changed, and an output signal having the changed amplitude is obtained from the output pads 51 and 52.

Each of the embodiments described above may include three or more coils.

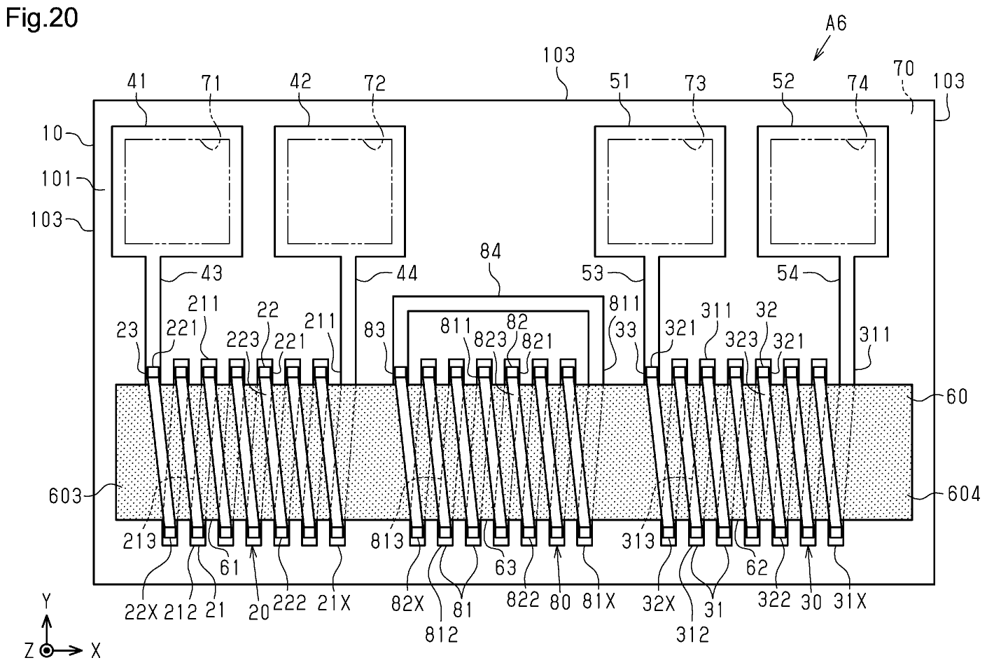

FIG. 20 is a diagram showing a modified example of a transformer chip A6. The transformer chip A6 includes a third coil 80 in addition to the first coil 20 and the second coil 30. The third coil 80 is arranged between the first coil 20 and the second coil 30 in the X-direction. The third coil 80 is insulated from the first coil 20 and the second coil 30. In this modified example, the third coil 80 is equal to the first coil 20 and the second coil 30 in number of turns.

The third coil 80 includes third substrate wires 81 and third connection wires 82 in the same manner as the first coil 20 and the second coil 30. The insulation member 60 is formed to extend through the first coil 20, the third coil 80, and the second coil 30. The insulation member 60 includes a third part 63 corresponding to the third coil 80.

The third substrate wires 81 are arranged next to each other in the X-direction. The third substrate wires 81 are arranged on the substrate main surface 101 of the substrate 10. The third substrate wires 81 extend in a direction intersecting the X-direction. In this modified example, the direction in which the third substrate wires 81 extend is equal to the direction in which the first substrate wires 21 and the second substrate wires 31 extend. The direction in which the third substrate wires 81 extend may differ from the direction in which the first substrate wires 21 and the second substrate wires 31 extend.

Each of the third substrate wires 81 includes a first end 811, a second end 812, and a first conductor 813. The insulation member 60 is formed to expose the first end 811 and the second end 812 of the third substrate wires 81 and cover the first conductor 813.

The third connection wires 82 are arranged next to each other in the X-direction. The third connection wires 82 extend in a direction intersecting the X-direction. The third connection wires 82 extend along the surface of the insulation member 60. The insulation member 60 separates a central part of each third connection wire 82 away from the third substrate wire 81 in the Z-direction. Each third connection wire 82 is located adjacent to two of the third substrate wires 81 in the X-direction and connects the first end 811 of one of the two of the third substrate wires 81 and the second end 812 of the other one of the two of the third substrate wires 81. The third connection wire 82 includes a third end 821 connected to the first end 811, a fourth end 822 connected to the second end 812, and a second conductor 823 located between the third end 821 and the fourth end 822.

In the third coil 80 of this modified example, the first end 811 of a third substrate wire 81X, which is located at the end close to the second coil 30, is not connected to the third connection wires 82. In this modified example, an end of the third coil 80 located close to the first coil 20 includes a third connector 83. The third connector 83 is connected to the third end 821 of a third connection wire 82X. In this modified example, the third coil 80 includes an end connection wire 84 connecting the first end 811 of the third substrate wire 81X to the third connector 83. The third coil 80 is looped by the end connection wire 84.

The insulation voltage of the transformer chip A6 is set by the distance between the first coil 20 and the third coil 80 and the distance between the third coil 80 and the second coil 30. Thus, the insulation voltage of the transformer chip A6 is readily changed by adjusting the relative position between the first coil 20 and the third coil 80 and the relative position between the third coil 80 and the second coil 30. The degree of design freedom in the transformer chip A6 is increased. The positions of the first coil 20, the second coil 30, and the third coil 80 maybe changed by masks (resist films) forming the coils 20, 80, 30. Thus, the transformer chip A6 is readily obtained without, for example, adding a new step to the manufacturing process of the transformer chip A6 or changing the number of times an existing step is repeated.

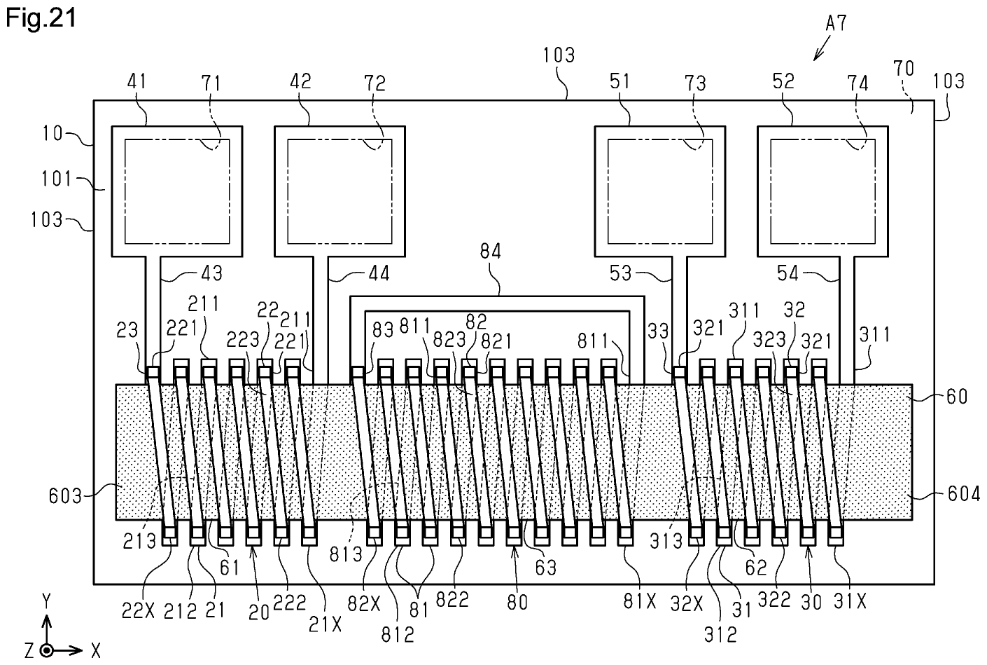

As in a modified example of a transformer chip A7 shown in FIG. 21, the number of turns in the third coil 80 maybe greater than the number of turns in the first coil 20 and the number of turns in the second coil 30. Alternatively, the number of turns in the third coil 80 maybe less than the number of turns in the first coil 20 and the number of turns in the second coil 30.

In the transformer chip A6 of the modified example shown in FIG. 20 and the transformer chip A7 shown in FIG. 21, the number of turns in the first coil 20 maybe greater than or less than the number of turns in the second coil 30.

In the embodiments and modified examples described above, the shape of each coil may be changed.

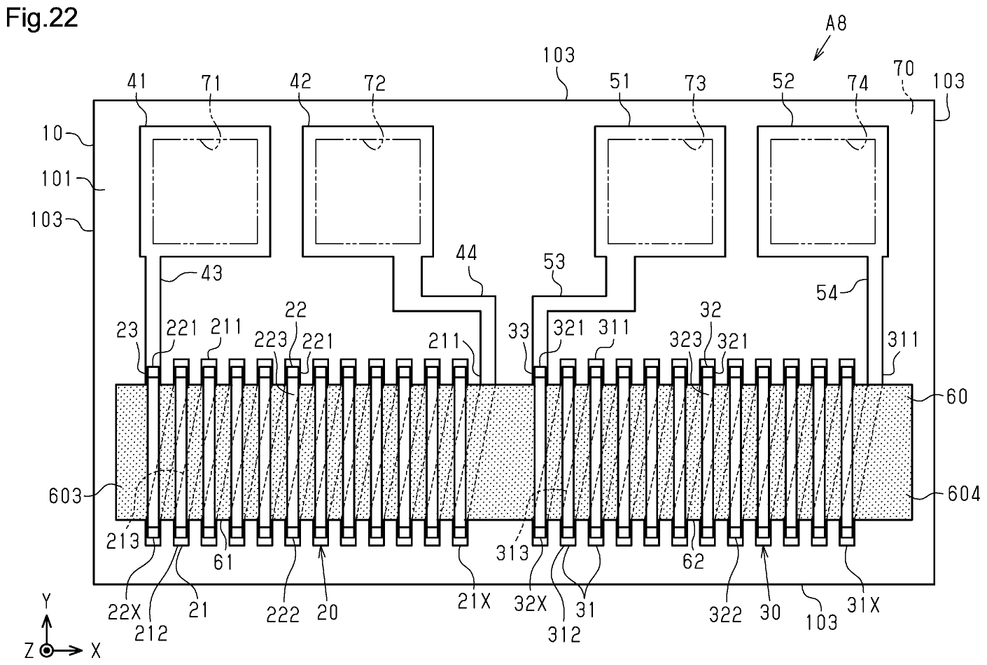

FIG. 22 is a diagram showing a modified example of a transformer chip A8. In the transformer chip A8, the first connection wires 22 of the first coil 20 extend in a direction orthogonal to the X-direction, that is, in the Y-direction. In the same manner, the second connection wires 32 of the second coil 30 extend in a direction orthogonal to the X-direction, that is, in the Y-direction. The first substrate wires 21 of the first coil 20 may extend in a direction orthogonal to the X-direction, that is, in the Y-direction. The second substrate wires 31 of the second coil 30 may extend in a direction orthogonal to the X-direction, that is, in the Y-direction.

In the embodiments and modified examples described above, connection of the first coil 20 to the input pads 41 and 42 and connection of the second coil 30 to the output pads 51 and 52 maybe changed.

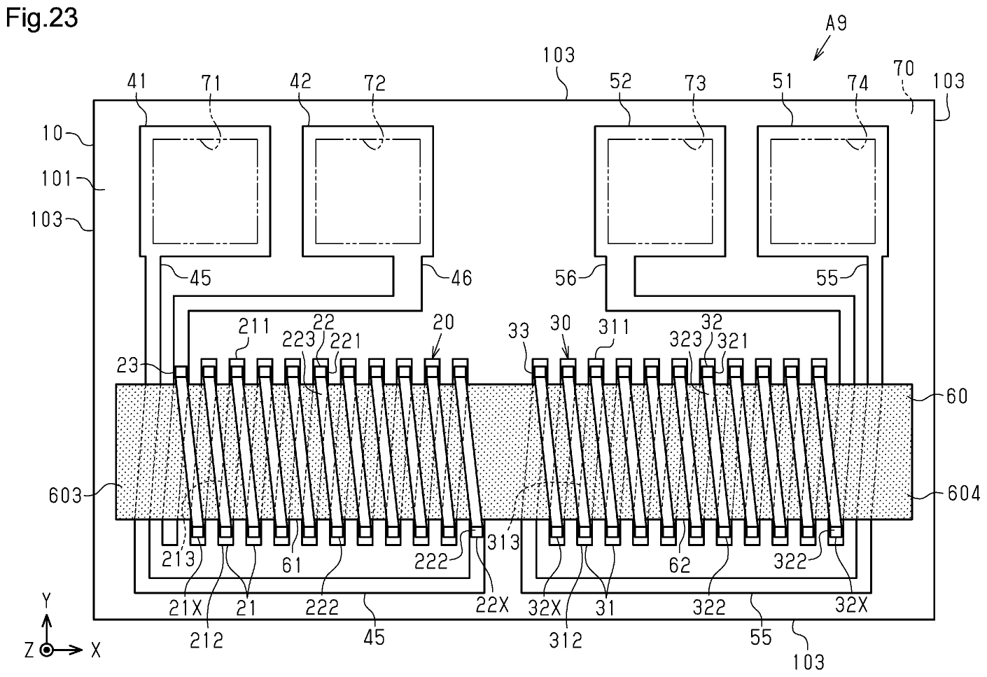

FIG. 23 is a diagram showing a modified example of a transformer chip A9. In the transformer chip A9, the input pads 41 and 42 are connected to the first coil 20 at an end of the first coil 20 located at a side opposite from the second coil 30. The output pads 51 and 52 are connected to the second coil 30 at an end of the second coil 30 located at a side opposite from the first coil 20.

The input pad 41 is connected to the fourth end 222 of the first connection wire 22X, which is one of the first connection wires 22 of the first coil 20 located close to the second coil 30, by a bypass wire 45, which bypasses the first coil 20. The input pad 42 is connected to the first connector 23 of the first coil 20 by a connection wire 46.

The output pad 51 is connected to the second connector 33 of the second coil 30 by a bypass wire 55, which bypasses the second coil 30. The output pad 52 is connected to the fourth end 322 of the second connection wire 32X, which is one of the second connection wires 32 of the second coil 30 located farthest from the first coil 20, by a connection wire 56.

The transformer chip A9 of this modified example, in which the input pads 41 and 42 are connected to the first coil 20 and the output pads 51 and 52 are connected to the second coil 30, obtains the same advantages as the transformer chip A1 of the first embodiment.

In the embodiments and modified examples described above, the structure of the substrate may be changed.

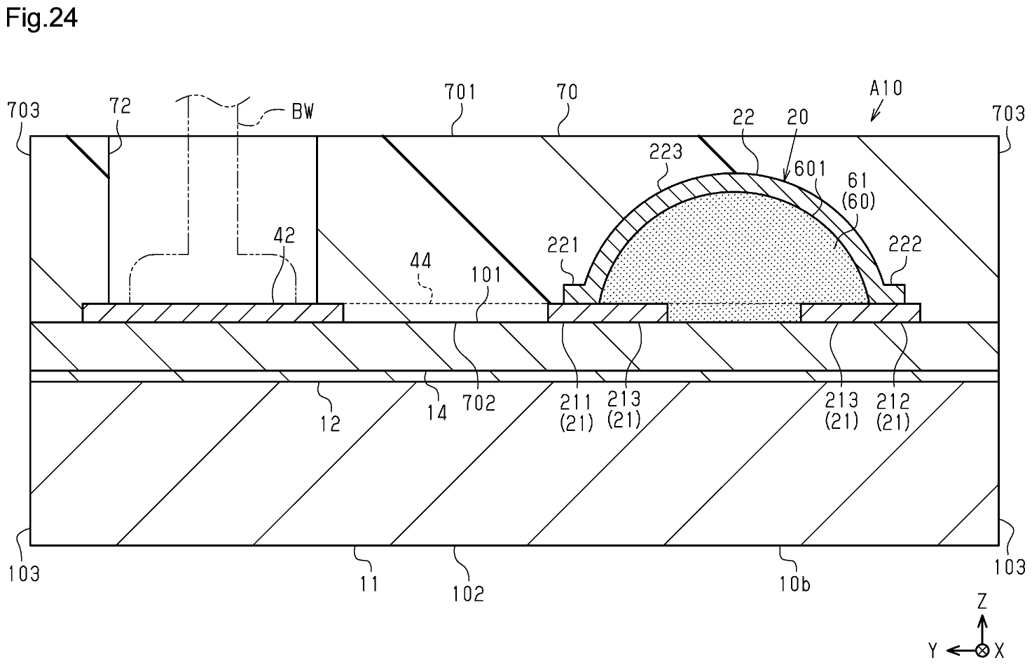

FIG. 24 is a diagram showing a modified example of a transformer chip A10. The transformer chip A10 includes a substrate 10b including the substrate body 11, the insulation film 12, and a substrate insulation layer 14. The substrate insulation layer 14 is formed on the upper surface of the insulation film 12. The first coil 20 and the second coil 30 are formed on the substrate main surface 101, which is the upper surface of the substrate insulation layer 14. The substrate insulation layer 14 is formed from an insulation resin such as a phenol resin or an insulation material such as SiO₂ or SiN. The substrate insulation layer 14 maybe formed of two or more insulation layers. The insulation film 12 maybe omitted. The transformer chip A10 also obtains the same advantages as the transformer chip A1 of the first embodiment. Additionally, a recess may be formed in the substrate insulation layer 14 to obtain a structure similar to the transformer chip B1 of the second embodiment and the transformer chip C1 of the third embodiment.

The insulation member 60 maybe arranged for each coil. In an example, in the first embodiment, the insulation member 60 maybe arranged so that the first part 61 corresponding to the first coil 20 and the second part 62 corresponding to the second coil 30 are separate members. In the same manner, in the transformer chips A6 and A7 of the modified examples shown in FIGS. 20 and 21, the insulation member 60 maybe arranged so that the first part 61, the second part 62, and the third part 63 are separate members. In the transformer chips A6 and A7 of the modified examples shown in FIGS. 20 and 21, the second part 62 maybe a member separate from the first part 61 and the third part 63. Alternatively, the first part 61 maybe a member separate from the third part 63 and the second part 62.

### CLAUSES

The technical aspects that are understood from the present disclosure will hereafter be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

### Clause 1

A transformer chip, including:
a substrate (10) including a substrate main surface (101);
a first coil (20) arranged on the substrate main surface (101); and
a second coil (30) arranged on the substrate main surface (101) and separated from the first coil (20) in a first direction (X), in which
the first coil (20) includes first substrate wires (21), arranged next to each other in the first direction (X) on the substrate main surface (101) and extending in a direction intersecting the first direction (X), and first connection wires (22), arranged next to each other in the first direction (X), each of the first connection wires (22) connecting two of the first substrate wires (21) that are located adjacent to each other in the first direction (X), and
the second coil (30) includes second substrate wires (31), arranged next to each other in the first direction (X) on the substrate main surface (101) and extending in a direction intersecting the first direction (X), and second connection wires (32), arranged next to each other in the first direction (X), each of the second connection wires (32) connecting two of the second substrate wires (31) that are located adjacent to each other in the first direction (X).

### Clause 2

The transformer chip according to clause 1, further including:
an insulation member (60, 60a, 60b), in which
each of the first substrate wires (21) and the second substrate wires (31) includes a first end (211, 311), a second end (212, 312) opposite to the first end (211, 311), and a first conductor (213, 313) located between the first end (211, 311) and the second end (212, 312), the insulation member (60, 60a, 60b) is in contact with the substrate main surface (101), covers the first substrate wires (21) and the second substrate wires (31) and exposes the first ends (211, 311) and the second ends (212, 312), and
the first connection wires (22) and the second connection wires (32) are formed along a surface (601) of the insulation member (60, 60a, 60b).

### Clause 3

The transformer chip according to clause 2, in which the insulation member (60) has an arcuate cross section that is orthogonal to the first direction (X) and bulged in a direction away from the substrate (10).

### Clause 4

The transformer chip according to clause 2, in which the insulation member (60c, 60d) has a quadrilateral cross section that is orthogonal to the first direction (X).

### Clause 5

The transformer chip according to clause 2, in which the substrate (10) includes a substrate back surface facing a direction opposite to the substrate main surface (101) and a recess (13) that is recessed from the substrate main surface (101) toward the substrate back surface,
the recess (13) extends in the first direction (X), and
the first substrate wires (21) and the second substrate wires (31) extend along a surface of the recess (13).

### Clause 6

The transformer chip according to clause 5, including: an insulation member (60a) formed to fill the recess (13), in which the first connection wires (22) and the second connection wires (32) are formed along a surface (601) of the insulation member (60a).

### Clause 7

The transformer chip according to clause 5, in which
the insulation member (60b) includes a first part (60b1) filling the recess (13) and a second part (60b2) projecting from the substrate main surface (101), and
the first connection wires (22) and the second connection wires (32) are formed along a surface (601) of the second part (60b2).

### Clause 8

The transformer chip according to any one of clauses 1 to 7, in which an inter-coil distance (D1) between the first coil (20) and the second coil (30) is greater than an inter-wire distance (P1) between two of the first substrate wires (21) located adjacent to each other in the first direction (X) or an inter-wire distance (P2) between two of the second substrate wires (31) located adjacent to each other in the first direction (X).

### Clause 9

The transformer chip according to any one of clauses 1 to 8, in which the first coil (20) is equal to the second coil (30) in number of turns.

### Clause 10

The transformer chip according to any one of clauses 1 to 8, in which the first coil (20) is greater than the second coil (30) in number of turns.

### Clause 11

The transformer chip according to any one of clauses 1 to 8, in which the first coil (20) is less than the second coil (30) in number of turns.

### Clause 12

The transformer chip according to any one of clauses 1 to 11, further including: two input pads (41, 42) arranged on the substrate main surface (101) and connected to two ends of the first coil (20); and two output pads (51, 52) arranged on the substrate main surface (101) and connected to two ends of the second coil (30).

### Clause 13

The transformer chip according to clause 12, further including: an encapsulation resin (70) encapsulating the first coil (20) and the second coil (30).

### Clause 14

The transformer chip according to clause 13, in which the encapsulation resin (70) includes an opening (71 to 74) exposing the input pads (41, 42) and the output pads (51, 52).

### Clause 15

The transformer chip according to any one of clauses 1 to 14, further including: a third coil (80) arranged between the first coil (20) and the second coil (30).

### Clause 16

The transformer chip according to clause 15, in which
the third coil (80) includes
   third substrate wires (81) arranged next to each other in the first direction (X) on the substrate main surface (101) and extending in a direction intersecting the first direction (X),
   third connection wires (82) arranged next to each other in the first direction (X), each of the third connection wires (82) connected to two of the third substrate wires (81) that are located adjacent to each other in the first direction (X), and
   a connect wire (84) connecting one of the third substrate wires (81) and one of the third connection wires (82) that are located at opposite ends in the first direction (X), and
the third coil (80) is looped.

### Clause 17

The transformer chip according to clause 15 or 16, in which the third coil (80) is equal to the first coil (20) or the second coil (30) in number of turns.

### Clause 18

The transformer chip according to clause 15 or 16, in which the third coil (80) differs from the first coil (20) or the second coil (30) in number of turns.

### Clause 19

The transformer chip according to clause 2 or 6, in which the insulation member (60, 60a to 60d) includes a material including a phenol resin.

### Clause 20

The transformer chip according to clause 13 or 14, in which the encapsulation resin (70) includes a material including a phenol resin.

### Clause 21

The transformer chip according to any one of clauses 1 to 20, in which the substrate (10) includes a substrate body (11) formed from a semiconductor material and an insulation layer (12) covering a main surface of the substrate body (11).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

### REFERENCE SIGNS LIST

A1 to A10, B1, C1) transformer chip
10, 10a, 10b) substrate
101) substrate main surface
102) substrate back surface
103) substrate side surface
104) upper surface
1041) first upper surface
1042) second upper surface
105) bottom surface
106) intermediate surface
1061) first intermediate surface
1062) second intermediate surface
11) substrate body
12) insulation film
13) recess
14) substrate insulation layer
20) first coil
21, 21X) first substrate wire
211) first end
212) second end
213) first conductor
2131) side portion
2132) side portion
2133) bottom portion
22, 22X) first connection wire
221) third end
222) fourth end
223) second conductor
23) first connector
30) second coil
31, 31X) second substrate wire
311) first end
312) second end
313) first conductor
3131) side portion
3132) side portion
3133) bottom portion
32, 32X) second connection wire
321) third end
322) fourth end
323) second conductor
33) second connector
41) input pad
42) input pad
43) pad connection wire
44) pad connection wire
45) bypass wire
46) connection wire
51) output pad
52) output pad
53) pad connection wire
54) pad connection wire
55) bypass wire
56) connection wire
60, 60a to 60d) insulation member
601) surface
6011) upper surface
6012) side surface
6013) side surface
603) first end
604) second end
60b1) first insulation portion
60b2) second insulation portion
61) first part
62) second part
63) third part
70) encapsulation resin
701) resin main surface
702) resin back surface
703) resin side surface
71) opening
72) opening
73) opening
74) opening
80) third coil
81, 81X) third substrate wire
811) first end
812) second end
813) first conductor
82, 82X) third connection wire
821) third end
822) fourth end
823) second conductor
83) third connector
84 end connection wire
90) inverter device
91) switching element
92) switching element
93) control circuit (ECU)
94) low-voltage circuit
95) high-voltage circuit
θ1) inclination angle
BW) bonding wire
D1) inter-coil distance
GND1, GND2) ground
L11 to L14) length
L21 to L24) length
P1, P2) wire gap
V1) first voltage
V2) second voltage
W11 to W14) width
W21 to W24) width

1. A transformer chip, comprising:
a substrate including a substrate main surface;
a first coil arranged on the substrate main surface; and
a second coil arranged on the substrate main surface and separated from the first coil in a first direction, wherein
the first coil includes first substrate wires, arranged next to each other in the first direction on the substrate main surface and extending in a direction intersecting the first direction, and first connection wires, arranged next to each other in the first direction, each of the first connection wires connecting two of the first substrate wires that are located adjacent to each other in the first direction, and
the second coil includes second substrate wires, arranged next to each other in the first direction on the substrate main surface and extending in a direction intersecting the first direction, and second connection wires, arranged next to each other in the first direction, each of the second connection wires connecting two of the second substrate wires that are located adjacent to each other in the first direction.

2. The transformer chip according to claim 1, further comprising:
an insulation member, wherein
each of the first substrate wires and the second substrate wires includes a first end, a second end opposite to the first end, and a first conductor located between the first end and the second end,
the insulation member is in contact with the substrate main surface, covers the first substrate wires and the second substrate wires and exposes the first ends and the second ends, and
the first connection wires and the second connection wires are formed along a surface of the insulation member.

3. The transformer chip according to claim 2, wherein the insulation member has an arcuate cross section that is orthogonal to the first direction and bulged in a direction away from the substrate.

4. The transformer chip according to claim 2, wherein the insulation member has a quadrilateral cross section that is orthogonal to the first direction.

5. The transformer chip according to claim 2, wherein
the substrate includes a substrate back surface facing a direction opposite to the substrate main surface and a recess that is recessed from the substrate main surface toward the substrate back surface,
the recess extends in the first direction, and
the first substrate wires and the second substrate wires extend along a surface of the recess.

6. The transformer chip according to claim 5, comprising:
an insulation member formed to fill the recess,
wherein the first connection wires and the second connection wires are formed along a surface of the insulation member.

7. The transformer chip according to claim 5, wherein
the insulation member includes a first part filling the recess and a second part projecting from the substrate main surface, and
the first connection wires and the second connection wires are formed along a surface of the second part.

8. The transformer chip according to claim 1, wherein an inter-coil distance between the first coil and the second coil is greater than an inter-wire distance between two of the first substrate wires located adjacent to each other in the first direction.

9. The transformer chip according to claim 1, wherein the first coil is equal to the second coil in number of turns.

10. The transformer chip according to claim 1, wherein the first coil is greater than the second coil in number of turns.

11. The transformer chip according to claim 1, wherein the first coil is less than the second coil in number of turns.

12. The transformer chip according to claim 1, further comprising:
two input pads arranged on the substrate main surface and connected to two ends of the first coil; and
two output pads arranged on the substrate main surface and connected to two ends of the second coil.

13. The transformer chip according to claim 12, further comprising:
an encapsulation resin encapsulating the first coil and the second coil.

14. The transformer chip according to claim 13, wherein the encapsulation resin includes an opening exposing the input pads and the output pads.

15. The transformer chip according to claim 1, further comprising:
a third coil arranged between the first coil and the second coil.

16. The transformer chip according to claim 15, wherein
the third coil includes
third substrate wires arranged next to each other in the first direction on the substrate main surface and extending in a direction intersecting the first direction,
third connection wires arranged next to each other in the first direction, each of the third connection wires connected to two of the third substrate wires that are located adjacent to each other in the first direction, and
a connect wire connecting one of the third substrate wires and one of the third connection wires that are located at opposite ends in the first direction, and the third coil is looped.

17. The transformer chip according to claim 15, wherein the third coil is equal to the first coil or the second coil in number of turns.

18. The transformer chip according to claim 15, wherein the third coil differs from the first coil or the second coil in number of turns.

19. The transformer chip according to claim 1, wherein the substrate includes a substrate body formed from a semiconductor material and an insulation layer covering a main surface of the substrate body.
